(19) United States
(12) Patent Application Publication
(10) Pub. No.: US 2026/0065951 A1
(43) Pub. Date: Mar. 5, 2026

(54) SEMICONDUCTOR MEMORY DEVICE AND MANUFACTURING METHOD THEREOF

(71) Applicant: Kioxia Corporation, Tokyo (JP)

(72) Inventors: Takayuki HASHIMOTO, Kuwana Mie (JP); Hanae ISHIHARA, Yokkaichi Mie (JP)

(21) Appl. No.: 19/063,582

(22) Filed: Feb. 26, 2025

(30) Foreign Application Priority Data
Sep. 5, 2024 (JP) 2024-153370

(51) Int. Cl. G11C 5/06; H01L 23/00; H01L 25/065; H10B 43/10; H10B 43/35; H10B 80/00

(52) U.S. Cl. CPC G11C 5/063; H10B 43/10; H10B 43/35; H10B 80/00

(57) ABSTRACT

A semiconductor memory device includes a stacked body including a plurality of conductive layers and insulating layers alternately stacked in a first direction; and a contact plug electrically connected to a corresponding one of the conductive layers and extending from a step surface of the corresponding conductive layer in the first direction to penetrate through a corresponding portion of the stacked body.

### CROSS-REFERENCE TO RELATED APPLICATION

This application is based upon and claims the benefit of priority from Japanese Patent Application No. 2024-153370, filed Sep. 5, 2024, the entire contents of which are incorporated herein by reference.

### FIELD

Embodiments described herein relate generally to a semiconductor memory device and a manufacturing method thereof.

### BACKGROUND

A semiconductor memory device such as a NAND flash memory may include a three-dimensional memory cell array in which a plurality of memory cells are disposed three-dimensionally.

### DESCRIPTION OF THE DRAWINGS

FIG. 1 is a perspective view showing an example of a semiconductor memory device according to a first embodiment;

FIG. 2 is a plan view showing a stacked body;

FIG. 3 is a cross-sectional view showing an example of memory cells of a three-dimensional structure;

FIG. 4 is a cross-sectional view showing an example of memory cells of a three-dimensional structure;

FIG. 5 is a plan view showing an example of the semiconductor memory device according to the first embodiment;

FIG. 6 is a schematic plan view showing a layout of a connection area and a memory cell region;

FIG. 7A is a perspective view showing an outline of a connection area of a block;

FIG. 7B is a perspective view showing an outline of the connection area of the block;

FIG. 8A is a plan view showing some conductive layers of the connection area in more detail;

FIG. 8B is a plan view showing some conductive layers of the connection area in more detail;

FIG. 9 is a cross-sectional view showing an example of a configuration of the semiconductor memory device according to the first embodiment;

FIG. 10 is a cross-sectional view showing an example of the configuration of the semiconductor memory device according to the first embodiment;

FIG. 11 is a cross-sectional view showing an example of the configuration of the semiconductor memory device according to the first embodiment;

FIG. 12A is a cross-sectional view showing an example of a manufacturing method of the semiconductor memory device according to the first embodiment;

FIG. 12B is a cross-sectional view showing an example of the manufacturing method of a semiconductor memory device subsequent to FIG. 12A;

FIG. 12C is a cross-sectional view showing an example of a manufacturing method of a semiconductor memory device subsequent to FIG. 12B;

FIG. 12D is a cross-sectional view showing an example of the manufacturing method of a semiconductor memory device, subsequent to FIG. 12C;

FIG. 12E is a cross-sectional view showing an example of the manufacturing method of the semiconductor memory device, subsequent to FIG. 12D;

FIG. 12F is a cross-sectional view showing an example of the manufacturing method of a semiconductor memory device, subsequent to FIG. 12E;

FIG. 12G is a cross-sectional view showing an example of the manufacturing method of the semiconductor memory device, subsequent to FIG. 12F;

FIG. 12H is a cross-sectional view showing an example of the manufacturing method of a semiconductor memory device, subsequent to FIG. 12G;

FIG. 12I is a cross-sectional view showing an example of the manufacturing method of the semiconductor memory device, subsequent to FIG. 12H;

FIG. 12J is a cross-sectional view showing an example of the manufacturing method of a semiconductor memory device, subsequent to FIG. 12I;

FIG. 12K is a cross-sectional view showing an example of the manufacturing method of the semiconductor memory device, subsequent to FIG. 12J;

FIG. 12L is a cross-sectional view showing an example of the manufacturing method of a semiconductor memory device, subsequent to FIG. 12K;

FIG. 12M is a cross-sectional view showing an example of the manufacturing method of the semiconductor memory device, subsequent to FIG. 12L;

FIG. 12N is a cross-sectional view showing an example of the manufacturing method of a semiconductor memory device, subsequent to FIG. 12M;

FIG. 13 is a cross-sectional view showing an example of a configuration of a semiconductor memory device according to a first comparative example;

FIG. 14A is a cross-sectional view showing an example of a manufacturing method of a semiconductor memory device according to a first modification of the first embodiment;

FIG. 14B is a cross-sectional view showing an example of the manufacturing method of the semiconductor memory device subsequent to FIG. 14A;

FIG. 14C is a cross-sectional view showing an example of the manufacturing method of the semiconductor memory device subsequent to FIG. 14B;

FIG. 14D is a cross-sectional view showing an example of the manufacturing method of the semiconductor memory device subsequent to FIG. 14C;

FIG. 14E is a cross-sectional view showing an example of the manufacturing method of the semiconductor memory device subsequent to FIG. 14D;

FIG. 14F is a cross-sectional view showing an example of the manufacturing method of the semiconductor memory device subsequent to FIG. 14E;

FIG. 14G is a cross-sectional view showing an example of the manufacturing method of the semiconductor memory device subsequent to FIG. 14F;

FIG. 14H is a cross-sectional view showing an example of the manufacturing method of the semiconductor memory device subsequent to FIG. 14G;

FIG. 14I is a cross-sectional view showing an example of the manufacturing method of the semiconductor memory device subsequent to FIG. 14H;

FIG. 14J is a cross-sectional view showing an example of the manufacturing method of the semiconductor memory device subsequent to FIG. 14I;

FIG. 15 is a diagram showing an example of a configuration of a semiconductor memory device according to a second embodiment;

FIG. 16 is a cross-sectional view showing an example of the configuration of the semiconductor memory device according to the second embodiment;

FIG. 17A is a cross-sectional view showing an example of a manufacturing method of the semiconductor memory device according to the second embodiment;

FIG. 17B is a cross-sectional view showing an example of the manufacturing method of the semiconductor memory device subsequent to FIG. 17A;

FIG. 17C is a cross-sectional view showing an example of the manufacturing method of the semiconductor memory device subsequent to FIG. 17B;

FIG. 17D is a cross-sectional view showing an example of the manufacturing method of the semiconductor memory device subsequent to FIG. 17C;

FIG. 17E is a cross-sectional view showing an example of the manufacturing method of the semiconductor memory device subsequent to FIG. 17D;

FIG. 17F is a cross-sectional view showing an example of the manufacturing method of the semiconductor memory device subsequent to FIG. 17E;

FIG. 17G is a cross-sectional view showing an example of the manufacturing method of the semiconductor memory device subsequent to FIG. 17F;

FIG. 17H is a cross-sectional view showing an example of the manufacturing method of the semiconductor memory device subsequent to FIG. 17G;

FIG. 17I is a cross-sectional view showing an example of the manufacturing method of the semiconductor memory device subsequent to FIG. 17H;

FIG. 17J is a cross-sectional view showing an example of the manufacturing method of the semiconductor memory device subsequent to FIG. 17I;

FIG. 17K is a cross-sectional view showing an example of the manufacturing method of the semiconductor memory device subsequent to FIG. 17J;

FIG. 17L is a cross-sectional view showing an example of the manufacturing method of the semiconductor memory device subsequent to FIG. 17K;

FIG. 17M is a cross-sectional view showing an example of the manufacturing method of the semiconductor memory device subsequent to FIG. 17L;

FIG. 17N is a cross-sectional view showing an example of the manufacturing method of the semiconductor memory device subsequent to FIG. 17M;

FIG. 17O is a cross-sectional view showing an example of the manufacturing method of the semiconductor memory device subsequent to FIG. 17N;

FIG. 17P is a cross-sectional view showing an example of the manufacturing method of the semiconductor memory device subsequent to FIG. 17O;

FIG. 17Q is a cross-sectional view showing an example of the manufacturing method of the semiconductor memory device subsequent to FIG. 17P;

FIG. 17R is a cross-sectional view showing an example of the manufacturing method of the semiconductor memory device subsequent to FIG. 17O;

FIG. 17S is a cross-sectional view showing an example of the manufacturing method of the semiconductor memory device subsequent to FIG. 17R;

FIG. 18 is a plan view showing an example of an embedding pattern of an insulating member according to the second embodiment;

FIG. 19 is a diagram showing an example of configurations of semiconductor memory devices according to the second embodiment and a second comparative example;

FIG. 20 is a diagram showing an example of a configuration of a semiconductor memory device according to a first modification of the second embodiment;

FIG. 21 is a cross-sectional view showing an example of a configuration of a semiconductor memory device according to a second modification of the second embodiment;

FIG. 22 is a cross-sectional view showing an example of a configuration of a semiconductor memory device according to a third modification of the second embodiment;

FIG. 23 is a cross-sectional view showing an example of the configuration of the semiconductor memory device according to the third modification of the second embodiment;

FIG. 24 is a cross-sectional view showing an example of a configuration of a semiconductor memory device according to a fourth modification of the second embodiment;

FIG. 25 is a cross-sectional view showing an example of a configuration of a semiconductor memory device according to a fifth modification of the second embodiment; and

FIG. 26 is a plan view showing an example of the configuration of an insulating member according to the fifth modification of the second embodiment.

### DETAILED DESCRIPTION

Embodiments provide a semiconductor memory device and a manufacturing method thereof capable of obtaining a more appropriate configuration.

In general, according to one embodiment, a semiconductor memory device includes a stacked body including a plurality of conductive layers and insulating layers alternately stacked in a first direction; and a contact plug electrically connected to a corresponding one of the conductive layers and extending from a step surface of the corresponding conductive layer in the first direction to penetrate through a corresponding portion of the stacked body.

Hereinafter, embodiments of the present disclosure will be described with reference to the drawings. The present disclosure is not limited to the embodiments. The drawings are schematic or conceptual, and proportions of various parts are not necessarily the same as actual proportions. In the specification and drawings, elements similar to those previously described with reference to the previous drawings are given the same reference numerals, and detailed descriptions thereof will be omitted as appropriate.

### First Embodiment

### First Configuration Example of Semiconductor Memory Device

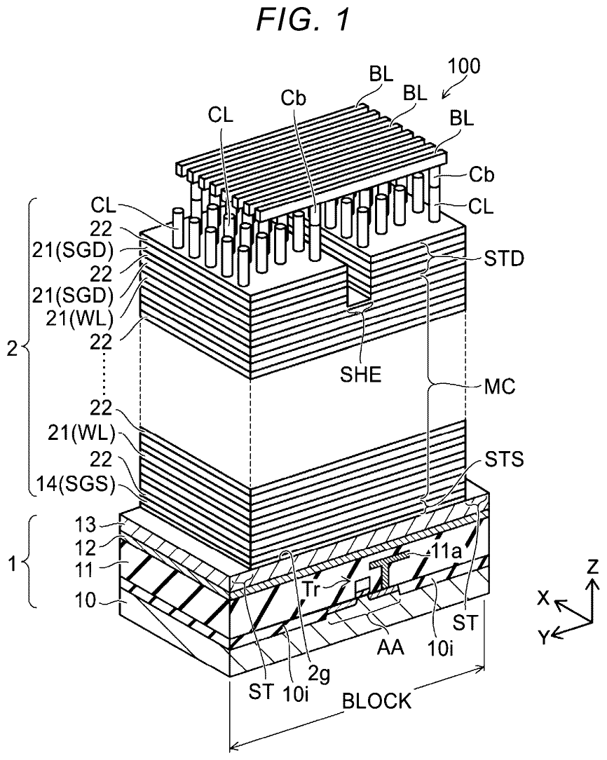

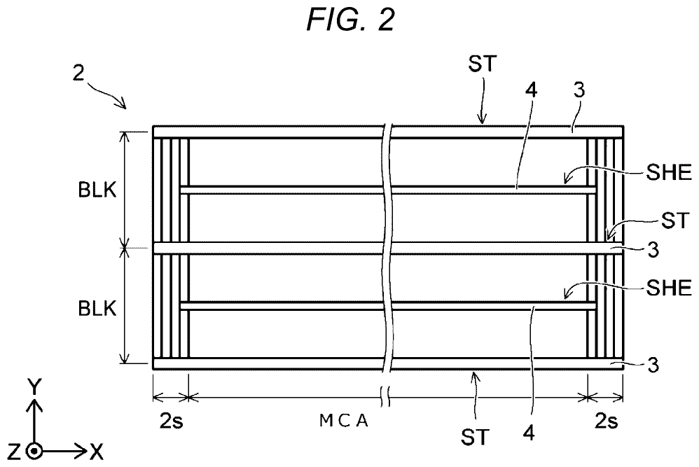

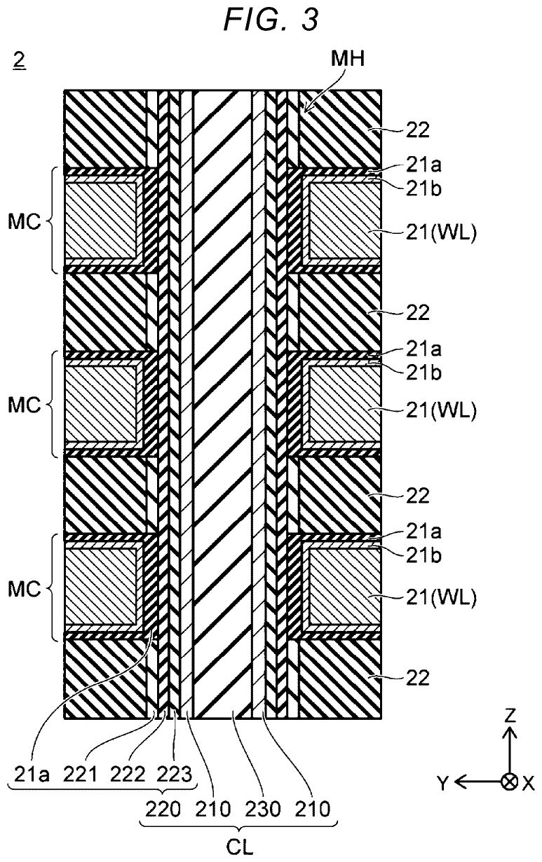

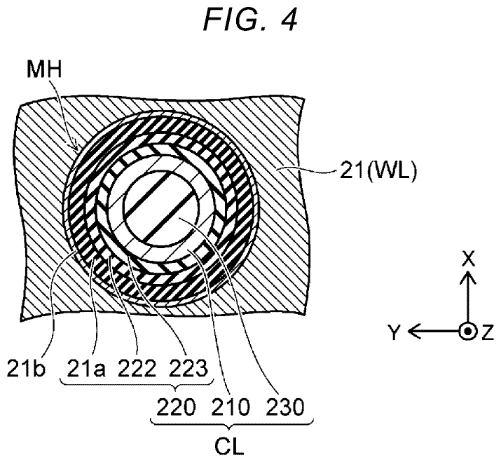

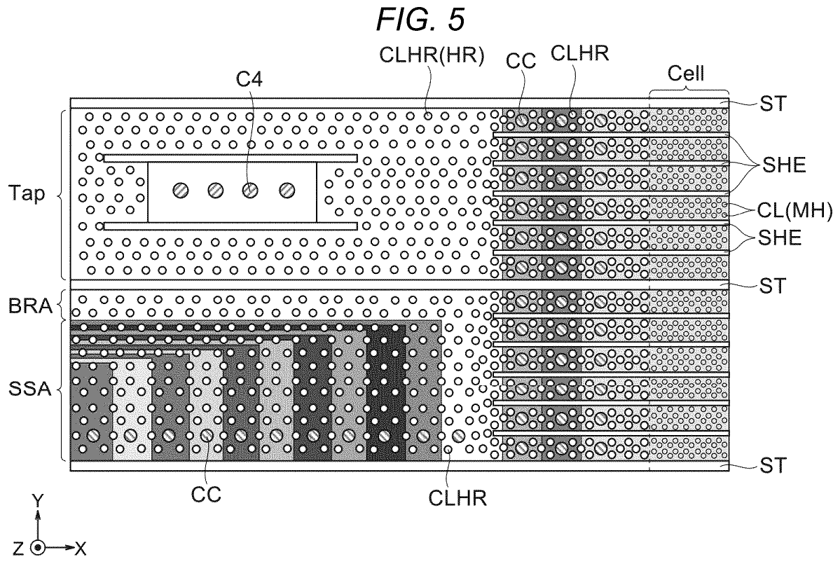

FIG. 1 is a perspective view showing an example of a semiconductor memory device 100 according to a first embodiment. FIG. 2 is a plan view showing a stacked body 2. In the specification, a stacking direction of the stacked body 2 is defined as a Z-axis direction. One direction perpendicular to the Z-axis direction is defined as a Y-axis direction. A direction perpendicular to each of the Z-axis direction and the Y-axis direction is defined as an X-axis direction. FIGS. 3 and 4 are cross-sectional views showing an example of memory cells of a three-dimensional structure. FIG. 5 is a plan view showing an example of the semiconductor memory device 100 according to the first embodiment. As shown in FIGS. 1 to 5, the semiconductor memory device 100 according to the first embodiment is a nonvolatile memory including a memory cell array having a three-dimensional structure.

The semiconductor memory device 100 includes a base portion 1, the stacked body 2, a plate-shaped portion 3, a plurality of columnar portions CL, and a plurality of insulating columns CLHR.

The base portion 1 includes a semiconductor wafer (substrate) 10, an insulating film 11, a conductive film 12, and a semiconductor portion 13. The insulating film 11 is provided on the semiconductor wafer 10. The conductive film 12 is provided on the insulating film 11. The semiconductor portion 13 is provided on the conductive film 12. The semiconductor wafer 10 is, for example, a silicon wafer. A conductivity type of the semiconductor wafer 10 is, for example, p-type. In a surface area of the semiconductor wafer 10, for example, an element isolation area 10i is provided. The element isolation area 10i is, for example, an insulating area including a silicon oxide film, and defines an active area AA on the surface area of the semiconductor wafer 10. In the active area AA, source and drain areas of a transistor Tr are provided. The transistor Tr configures a complementary metal oxide semiconductor (CMOS) circuit as a control circuit for the nonvolatile memory. The insulating includes, for example, a silicon oxide film, and insulates the transistor Tr. In the insulating film 11, a wiring 11a is provided. The wiring 11a is electrically connected to the transistor Tr. The conductive film 12 includes a conductive metal, for example, tungsten (W). The semiconductor portion 13 includes, for example, n-type silicon. A part of the semiconductor portion 13 may contain undoped silicon.

The stacked body 2 is located above the semiconductor portion 13 in the Z-axis direction. The stacked body 2 is configured with a plurality of conductive layers 21 as a plurality of first conductive layers and a plurality of insulating layers 22 as a plurality of first insulating layers alternately stacked in the Z-axis direction. The plurality of conductive layers 21 are stacked to be spaced with each other and the insulating layers 22 are interposed therebetween. The conductive layer 21 includes a conductive metal, for example, tungsten. The insulating layer 22 includes, for example, silicon oxide. The insulating layer 22 insulates the conductive layers 21 from each other. The number of stacked conductive layers 21 and insulating layers 22 are each freely selected. The insulating layer 22 may be, for example, a gap. Between the stacked body 2 and the semiconductor portion 13, for example, an insulating film 2g is provided. The insulating film 2g includes, for example, a silicon oxide film. The insulating film 2g may include a high-dielectric material having a higher relative dielectric constant than silicon oxide. The high-dielectric material may be, for example, an oxide such as hafnium oxide.

The conductive layer 21 includes at least one source-side select gate SGS, a plurality of word lines WL, and at least one drain-side select gate SGD. The source-side select gate SGS is a gate electrode of a source-side select transistor STS. The word line WL is a gate electrode of a memory cell MC. The drain-side select gate SGD is a gate electrode of a drain-side selection transistor STD. The source-side select gate SGS is provided in a lower area of the stacked body 2. The drain-side select gate SGD is provided in an upper area of the stacked body 2. The lower area refers to an area of the stacked body 2 closer to the base portion 1, and the upper area refers to an area of the stacked body 2 farther from the base portion 1. The word line WL is provided between the source-side select gate SGS and the drain-side select gate SGD.

Among the plurality of insulating layers 22, a Z-axis thickness of the insulating layer 22 that insulates the source-side select gate SGS from the word line WL may be made thicker than, for example, a Z-axis thickness of the insulating layer 22 that insulates the word line WL from the word line WL. A cover insulating film may be provided on the uppermost insulating layer 22 farthest from the base portion 1. The cover insulating film includes, for example, silicon oxide.

The semiconductor memory device 100 includes a plurality of memory cells MC connected in series between the source-side select transistor STS and the drain-side select transistor STD. A structure in which the source-side select transistor STS, the memory cells MC, and the drain-side select transistor STD are connected in series is called a “memory string” or a “NAND string”. The memory string is connected to a bit line BL via a contact Cb, for example. The bit line BL is provided above the stacked body 2 and extends in the Y-axis direction.

In the stacked body 2, a plurality of deep slits ST and a plurality of shallow slits SHE are provided. As shown in FIG. 2, the slit ST extends in the X-axis direction in a planar layout. The slit ST is provided in the stacked body 2 to penetrate the stacked body 2 from an upper end of the stacked body 2 across the base portion 1 in a cross section in the Z-axis direction (stacking direction). The plate-shaped portion 3 in FIG. 2 is provided in the slit ST. The plate-shaped portion 3 is, for example, an insulating film such as a silicon oxide film. Alternatively, the plate-shaped portion 3 may contain a conductive material such as a conductive metal (that is, tungsten, copper) electrically connected to the semiconductor portion 13, and may be electrically insulated from the stacked body 2 by an insulating film. In a planar layout, the slit SHE extends in the X-axis direction substantially parallel to the slit ST. The slit SHE is provided from the upper end of the stacked body 2 to midway of the stacked body 2 in the cross section in the Z-axis direction. In the slit SHE, for example, an insulator 4 is provided. The insulator 4 is, for example, an insulating film such as a silicon oxide film.

As shown in FIG. 2, the stacked body 2 includes staircase portions 2s and a memory cell array MCA. The staircase portions 2s are provided at edge portions of the stacked body 2. The memory cell array MCA is interposed between the staircase portions 2s or surrounded by the staircase portions 2s. The slit ST is provided from the staircase portion 2s at one end of the stacked body 2 across the memory cell array MCA to the staircase portion 2s at the other end of the stacked body 2. The slit SHE is provided in at least the memory cell array MCA.

A portion of the stacked body 2 interposed between the two slits ST (plate-shaped portions 3) is called a block BLK. One block is, for example, the smallest unit of data erasure. The slit SHE (insulator 4) is provided in the block. The stacked body 2 between the slit ST and the slit SHE is called a finger. The drain-side select gate SGD is divided for each finger. Therefore, when writing and reading data, one finger in the block can be set to a selected state by the drain-side select gate SGD.

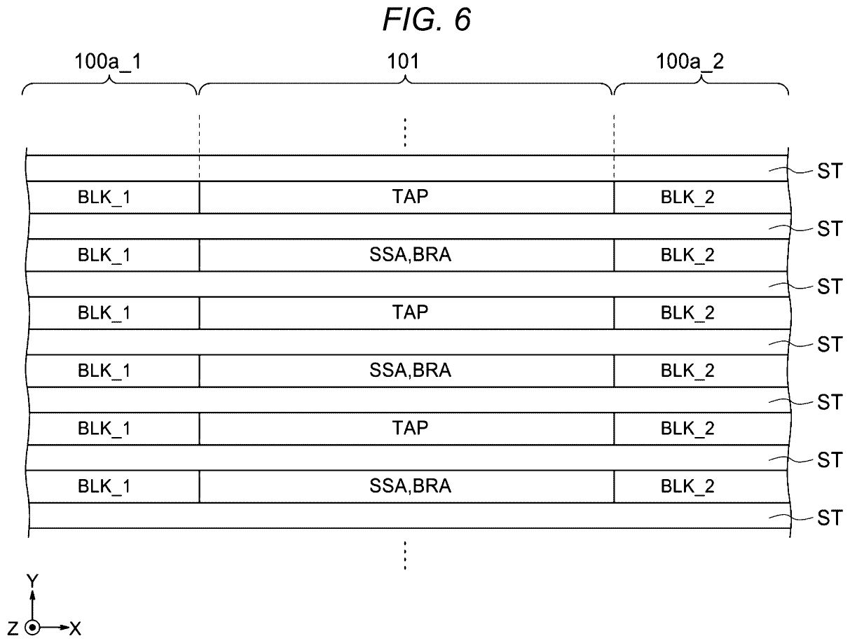

As shown in FIG. 5, the memory cell array MCA includes a cell area Cell and other areas. In the cell area Cell, the plurality of columnar portions CL are provided in the memory hole MH. As the areas other than the cell area Cell, a tap area Tap, a staircase area SSA, and a bridge area BRA are provided. The tap area Tap is provided in the block BLK adjacent to the staircase area SSA and the bridge area BRA in the Y-axis direction with the slit ST interposed therebetween. The tap area Tap may be provided between cell areas in the X-axis direction as shown in FIG. 6. The staircase area SSA and the bridge area BRA may also be provided between cell areas in the X-axis direction. The staircase area SSA is an area where a plurality of contact plugs CC are provided. As shown in FIG. 6, the bridge area BRA is provided to electrically connect each of wiring layers of the word lines WL of the blocks BLK adjacent in the X-axis direction with the staircase area SSA interposed therebetween. The tap area Tap is an area in which a contact plug C4 is provided. Each of the contact plugs CC and C4 extends, for example, in the Z-axis direction. The contact plugs CC are each electrically connected to, for example, the conductive layer 21. The contact plug C4 is electrically connected to, for example, the wiring 11a for supplying power to the transistor Tr or the like. The contact plugs CC and C4 are made of, for example, a low-resistance metal such as copper or tungsten.

An insulating film (not shown) is provided around each of the contact plugs CC and C4. Thus, the contact plugs CC and C4 are electrically insulated from the stacked body 2. The contact plugs CC and C4 can electrically connect a wiring or the like above the stacked body 2 to a wiring or the like below the stacked body 2 while being insulated from the stacked body 2. The insulating film may be, for example, a silicon oxide film.

Each of the plurality of columnar portions CL is provided in a memory hole MH in the stacked body 2. The memory hole MH penetrates the stacked body 2 from the upper end of the stacked body 2 in the stacking direction (Z-axis direction) of the stacked body 2, and extends across inside of the stacked body 2 and inside of the semiconductor portion 13. As shown in FIGS. 3 and 4, each of the plurality of columnar portions CL includes a semiconductor body 210 as a semiconductor pillar, a memory film 220, and a core layer 230. The semiconductor body 210 extends in the stacked body 2 in the stacking direction of the stacked body 2 (Z-axis direction). The semiconductor body 210 is electrically connected to the semiconductor portion 13. The memory film 220 is provided with a charge trapping portion between the semiconductor body 210 and the conductive layer 21. A plurality of columnar portions CL selected one by one from each finger are commonly connected to one bit line BL via the contact Cb. Each of the columnar portions CL is provided in, for example, the cell area (Cell) in FIG. 5.

As shown in FIGS. 3 and 4, a shape of the memory hole MH in an XY plane is, for example, a circle or an ellipse. A block insulating film 21a in a part of the memory film 220 may be provided between the conductive layer 21 and the insulating layer 22. The block insulating film 21a is, for example, a silicon oxide film or a metal oxide film. One example of a metal oxide is aluminum oxide. A barrier film 21b may be provided between the conductive layer 21 and the insulating layer 22 and between the conductive layer 21 and the memory film 220. For example, when the conductive layer 21 is made of tungsten, a stacked film of titanium nitride and titanium is selected as the barrier film 21b. The block insulating film 21a prevents back-tunneling of charges from the conductive layer 21 to the memory film 220 side. The barrier film 21b improves adhesion between the conductive layer 21 and the block insulating film 21a.

A shape of the semiconductor body 210 is, for example, cylindrical. The semiconductor body 210 includes, for example, silicon. Silicon is, for example, polysilicon obtained by crystallizing amorphous silicon. The semiconductor body 210 is, for example, undoped silicon. The semiconductor body 210 may be p-type silicon. The semiconductor body 210 serves as a channel of each of the drain-side select transistor STD, the memory cell MC, and the source-side select transistor STS.

Portions of the memory film 220 other than the block insulating film 21a are provided between an inner wall of the memory hole MH and the semiconductor body 210. A shape of the memory film 220 is, for example, cylindrical. A plurality of memory cells MC are provided with a storage area between the semiconductor body 210 and the conductive layer 21 serving as the word line WL, and are stacked in the Z-axis direction. The memory film 220 includes, for example, a cover insulating film 221, a charge trapping film 222, and a tunnel insulating film 223. The semiconductor body 210, the charge trapping film 222, and the tunnel insulating film 223 each extend in the Z-axis direction.

The cover insulating film 221 is provided between the insulating layer 22 and the charge trapping film 222. The cover insulating film 221 is made of, for example, silicon oxide. The cover insulating film 221 protects the charge trapping film 222 from etching when a sacrificial film provided between the insulating layers 22 is replaced with the conductive layer 21 in a manufacturing process. The cover insulating film 221 may be removed from between the conductive layer 21 and the memory film 220 in a replacement step. Here, for example, the block insulating film 21a is provided between the conductive layer 21 and the charge trapping film 222 as shown in FIGS. 3 and 4. When the conductive layer 21 is not formed by the replacement step, the cover insulating film 221 may not be provided.

The charge trapping film 222 is provided between the block insulating film 21a and the cover insulating film 221, and the tunnel insulating film 223. The charge trapping film 222 includes, for example, silicon nitride, and has trap sites in the film that trap charges. A portion of the charge trapping film 222 interposed between the conductive layer 21 serving as the word line WL and the semiconductor body 210 configures the storage area of the memory cell MC as the charge trapping portion. A threshold voltage of the memory cell MC varies depending on whether charges are trapped in the charge trapping portion or the amount of charges trapped in the charge trapping portion. Accordingly, the memory cell MC can store information.

The tunnel insulating film 223 is provided between the semiconductor body 210 and the charge trapping film 222. The tunnel insulating film 223 is made of, for example, silicon oxide or a combination of silicon oxide and silicon nitride. The tunnel insulating film 223 is a potential barrier between the semiconductor body 210 and the charge trapping film 222. For example, when electrons are injected from the semiconductor body 210 into the charge trapping portion (write operation) and when holes are injected from the semiconductor body 210 into the charge trapping portion (erase operation), electrons and holes each pass through the potential barrier of the tunnel insulating film 223 (tunneling).

The core layer 230 embeds an inner space of the cylindrical semiconductor body 210. The core layer 230 has, for example, a columnar shape. The core layer 230 is made of, for example, an insulating film such as a silicon oxide film.

Each of the plurality of insulating columns CLHR shown in FIG. 5 is provided in a hole HR in the stacked body 2. The hole HR penetrates the stacked body 2 from the upper end of the stacked body 2 in the Z-axis direction, and extends across inside of the stacked body 2 and inside of the semiconductor portion 13. The insulating column CLHR is made of an insulating material such as a silicon oxide film. Each of the insulating columns CLHR may have the same structure as the columnar portion CL. The insulating columns CLHR are provided, for example, in the tap area Tap, the staircase area SSA, and the bridge area BRA. The insulating columns CLHR function as support members for holding gaps formed in the step area and the tap area when a sacrificial film (not shown) is replaced with the conductive layer 21 (replacement step). The hole HR of the insulating column CLHR has a larger diameter (width in the X-axis direction or the Y-axis direction) than the columnar portion CL.

As shown in FIG. 1, the semiconductor memory device 100 further includes a semiconductor portion 14. The semiconductor portion 14 is located between the stacked body 2 and the semiconductor portion 13. The semiconductor portion 14 is provided between the insulating layer 22 that is closest to the semiconductor portion 13 among the insulating layers 22 and the insulating film 2g. A conductivity type of the semiconductor portion 14 is, for example, n-type. The semiconductor portion 14 functions as, for example, the source-side select gate SGS.

FIG. 6 is a schematic plan view showing a layout of a connection area 101 and a memory cell region 100a. The memory cell region 100a includes a first memory cell region 100a_1 and a second memory cell region 100a_2 adjacent to each other. Each of the first memory cell region 100a_1 and the second memory cell region 100a_2 includes a plurality of blocks BLK. In the Y-axis direction, the plurality of blocks BLK are each separated by the slits ST extending in the X-axis direction.

Both the first memory cell region 100a_1 and the second memory cell region 100a_2 include the above-described plurality of columnar portions CL (memory holes MH), and include a plurality of memory cells arranged three-dimensionally. The memory cells are formed at intersections of a plurality of word lines WL and columnar portions CL.

For convenience, the block BLK belonging to the first memory cell region 100a_1 is referred to as a block BLK 1. The block BLK belonging to the second memory cell region 100a_2 is referred to as a block BLK 2.

The connection area 101 is provided between the first memory cell region 100a_1 and the second memory cell region 100a_2 in the X-axis direction intersecting the Z-axis direction, and includes the tap area Tap, the staircase area SSA, and the bridge area BRA for each block BLK. The staircase area SSA and the bridge area BRA are hereinafter also referred to as the staircase area SSA and the like.

As described above, the tap area Tap and the staircase area SSA and the like are adjacent to each other in the Y-axis direction with the slit ST interposed therebetween. As shown in FIG. 6, the tap areas Tap and the staircase areas SSA and the like are provided alternately in the Y-axis direction. Although not shown in the drawings, the tap areas Tap and the staircase areas SSA and the like are also provided alternately in the X-axis direction. That is, the tap areas Tap and the staircase areas SSA and the like are alternately provided in the Y-axis direction with the slits ST interposed therebetween, and are alternately provided in the X-axis direction with the cell areas Cell (blocks BLK) interposed therebetween.

In the staircase area SSA, end portions of each of the select gate line (source-side select gate) SGS and the plurality of word lines WL are formed in a staircase shape with steps provided in the X-axis direction in order from a lower side. In other words, in the staircase area SSA, each of the select gate line SGS and the word lines WL is provided with a terrace portion (also referred to as staircase, staircase portion, or lead-out portion) at an end portion that does not overlap with the lower wiring layer (conductive layer). The contact plug CC shown in FIG. 5 is formed on each terrace portion. Voltages can be applied separately to each of the select gate line SGS and the plurality of word lines WL via the contact plugs CC. As such, the staircase area SSA is provided as a terrace area for connecting a plurality of contacts to each of a plurality of conductive layers connected to each of the select gate line SGS and a plurality of word lines WL.

The contact plugs CC are electrically connected to the contact plugs C4 in the tap area in FIG. 5 via an upper layer wiring (not shown), and are electrically connected to a row decoder provided below the memory cell array via the contact plugs C4. Accordingly, the row decoder can control a voltage of each conductive layer 21 (word line WL) via the contact plugs CC. A diameter of the contact plugs CC and C4 is larger than a diameter of the insulating column CLHR.

In the bridge area BRA, a plurality of third conductive layers each corresponding to the select gate line SGS and the plurality of word lines WL are stacked to be spaced from each other in the Z-axis direction. The third conductive layer electrically connects the conductive layer 21 (select gate line SGS and the plurality of word lines WL) of the first memory cell region 100a_1 to the conductive layer 21 (select gate line SGS and the plurality of word lines WL) of the second memory cell region 100a_2. Therefore, the first and second memory cell regions 100a_1 and 100a_2 can function as one memory cell array MCA.

As such, since the connection area 101 is disposed in an intermediate portion of the memory cell array MCA, the contact plug CC is positioned in an intermediate portion of the wiring of the word line WL, and a distance from the contact plug CC to the end portion of the word line WL can be shortened. Thus, the semiconductor memory device 100 can quickly supply power to the end portions of the word lines WL via the contact plugs CC, thereby facilitating voltage control of the word lines WL. Since the memory cell regions 100a_1 and 100a_2 can be disposed on both sides of one connection area 101, a scale (storage capacity) of the memory cell array MCA can be increased while maintaining an operating speed.

The bridge area BRA has the same stacked body structure as the first and second memory cell regions 100a_1 and 100a_2. Therefore, the stacked body in the bridge area BRA is configured by alternately stacking a plurality of conductive layers 21 and a plurality of insulating layers 22 in the Z-axis direction. That is, a plurality of conductive layers 21 serving as a plurality of third conductive layers are stacked to be spaced from each other and the insulating layers 22 are interposed therebetween. The insulating layer 22 may be an air gap as described above.

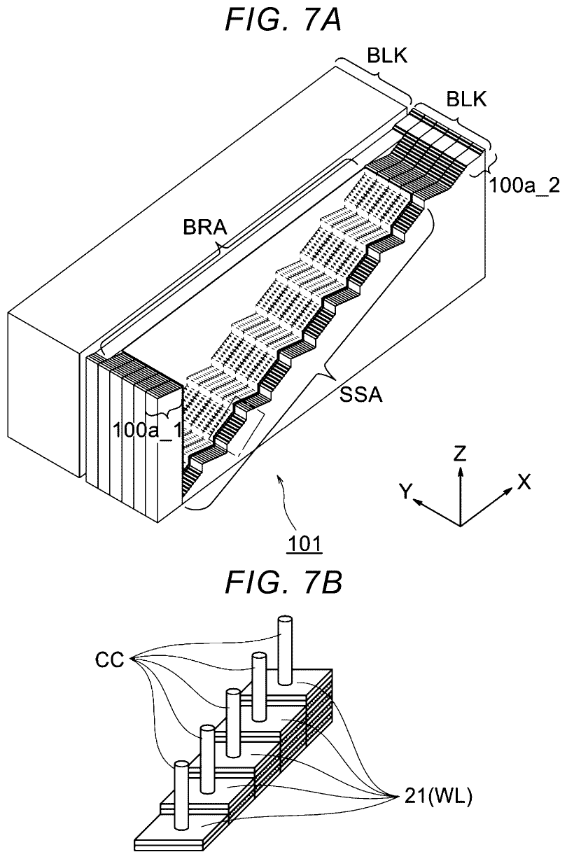

FIGS. 7A and 7B are perspective views showing an outline of the connection area 101 of a certain block BLK. The staircase area SSA of the connection area 101 is provided in a staircase shape to connect each of a plurality of contact plugs CC to each of the conductive layers 21 (word lines WL). In the bridge area BRA, a plurality of conductive layers 21 electrically connect the conductive layers 21 (word lines WL) of the first and second memory cell regions 100a_1 and 100a_2 to each other.

The bridge area BRA in the connection area 101 is provided adjacent to the staircase area SSA in the Y-axis direction (direction substantially perpendicular to extension direction of the slit ST) and is not engraved in a staircase shape. Therefore, the bridge area BRA has the same number of conductive layers 21 and the same number of insulating layers 22 as the number of stacked bodies 2 in the first and second memory cell regions 100a_1 and 100a_2.

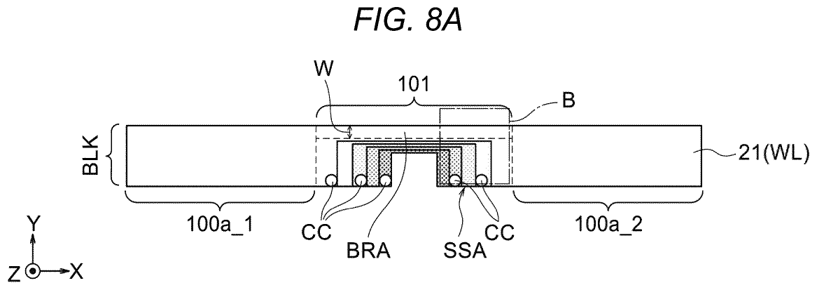

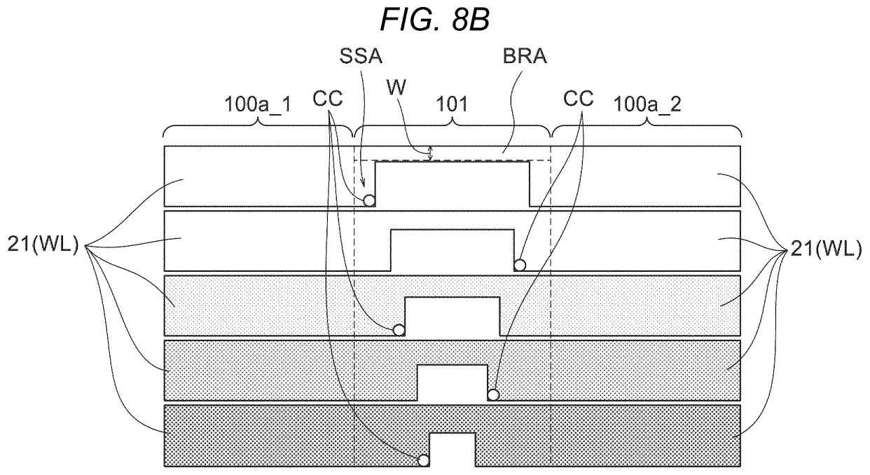

FIGS. 8A and 8B are plan views showing some conductive layers 21 in the connection area 101 in more detail. FIG. 8A shows the conductive layers 21 in a stacked state, and FIG. 8B shows each layer of the conductive layers 21 separately. In FIGS. 8A and 8B, five conductive layers 21 are shown. Of course, the number of conductive layers 21 may be four or less, or six or more. FIGS. 8A and 8B show one block BLK portion, and the columnar portion CL (memory hole MH), the insulating column CLHR, and the slit SHE shown in FIG. 5 are not shown.

As shown in FIG. 8A, the staircase area SSA of the connection area 101 is formed in a staircase shape such that a surface (tread surface) of each conductive layer 21 is visible from the Z-axis direction. The surface (tread surface) of each conductive layer 21 has a width (area) that allows the contact plug CC to be connected in the Z-axis direction. In FIG. 8A, the staircase portions of the staircase area SSA face each other on both sides of the connection area 101 in the X-axis direction. As shown in FIGS. 8A and 8B, the contact plug CC is provided for each conductive layer 21 in the staircase area SSA, and is connected to the tread surface of each conductive layer 21. For example, in the example shown in FIGS. 8A and 8B, the contact plugs CC are alternately connected to the left and right staircase portions of the staircase area SSA. More specifically, in the uppermost conductive layer 21, the contact plug CC is connected to the tread surface of the staircase portion on the left side of the staircase area SSA. In the second conductive layer 21, the contact plug CC is connected to the tread surface of the staircase portion on the right side of the staircase area SSA. In the third conductive layer 21, the contact plug CC is connected to the tread surface of the staircase portion on the left side of the staircase area SSA. In the fourth conductive layer 21, the contact plug CC is connected to the tread surface of the staircase portion on the right side of the staircase area SSA. In the fifth (lowest) conductive layer 21, the contact plug CC is connected to the tread surface of the staircase portion on the left side of the staircase area SSA.

The staircase area SSA may be provided on only one side of the connection area 101 in the X-axis direction. Here, the contact plug CC is connected to the tread surface of the staircase portion provided on one side of the connection area 101.

Since one contact plug CC is provided for each conductive layer 21, the conductive layer 21 in the memory cell region on the side to which the contact plug CC is not connected is electrically connected to the contact plug CC via the bridge area BRA. For example, the uppermost conductive layer 21 of the second memory cell region 100a_2 on the right side is not provided with the contact plug CC. Therefore, the uppermost conductive layer 21 of the second memory cell region 100a_2 on the right side is electrically connected to the contact plug CC provided in the uppermost conductive layer 21 of the first memory cell region 100a_1 on the left side via the uppermost conductive layer 21 of the bridge area BRA. The second conductive layer 21 in the first memory cell region 100a_1 on the left side is not provided with the contact plug CC. Therefore, the second conductive layer 21 of the first memory cell region 100a_1 on the left side is electrically connected to the contact plug CC provided in the second conductive layer 21 of the second memory cell region 100a_2 on the right side via the second conductive layer 21 of the bridge area BRA. As such, one of the memory cell regions 100a_1 and 100a_2 on both sides of the connection area 101 is electrically connected to the contact plug CC provided in the other memory cell region via the bridge area BRA.

### Second Configuration Example of Semiconductor Memory Device

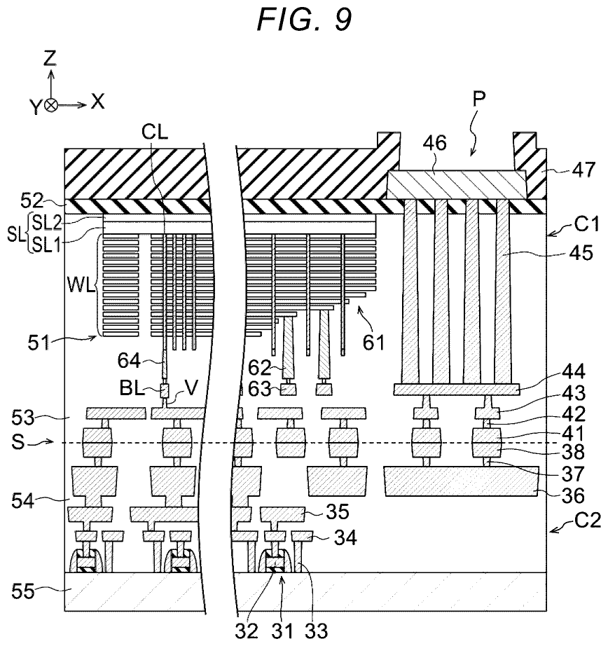

FIG. 9 is a cross-sectional view showing an example of a configuration of the semiconductor memory device according to the first embodiment. The semiconductor memory device shown in FIG. 9 is a three-dimensional memory in which an array chip C1 and a circuit chip C2 are bonded together.

The array chip C1 includes a memory cell array 51 including a plurality of memory cells arranged three-dimensionally, an insulating film 52 on the memory cell array 51, and an interlayer insulating film 53 below the memory cell array 51. The insulating film 52 is, for example, a silicon oxide film or a silicon nitride film. The interlayer insulating film 53 is, for example, a silicon oxide film or a stacked film including a silicon oxide film and another insulating film.

The circuit chip C2 is provided below the array chip C1. A reference mark S indicates a bonding surface between the array chip C1 and the circuit chip C2. The circuit chip C2 includes an interlayer insulating film 54 and a substrate 55 below the interlayer insulating film 54. The interlayer insulating film 54 is, for example, a silicon oxide film or a stacked film including a silicon oxide film and another insulating film. The substrate 55 is an example of a first substrate, and is, for example, a semiconductor substrate such as a silicon substrate. FIG. 9 shows the X-axis direction and the Y-axis direction that are parallel to the surface of the substrate 55, that is, the upper surface of the substrate 55 and perpendicular to each other, and the Z-axis direction that is perpendicular to the surface of the substrate 55.

The array chip C1 includes a plurality of word lines WL and a source line SL as a plurality of electrode layers in the memory cell array 51. FIG. 9 shows a staircase portion 61 of the memory cell array 51. Each word line WL is electrically connected to a word wiring layer 63 via a contact plug 62. Each columnar portion CL penetrating a plurality of word lines WL is electrically connected to the bit line BL via a via plug 64, and is also electrically connected to the source line SL. The source line SL includes a first layer SL1 that is semiconductor layer and a second layer SL2 that is a metal layer. The reference mark V indicates a via plug provided below the bit line BL.

The circuit chip C2 includes a plurality of transistors 31. Each transistor 31 includes a gate electrode 32 provided on the substrate 55 with a gate insulating film interposed therebetween, and a source diffusion layer and a drain diffusion layer (not shown) provided in the substrate 55. The circuit chip C2 also includes a plurality of contact plugs 33 provided on the source diffusion layers or drain diffusion layers of the transistors 31, a wiring layer 34 provided on the contact plugs 33 and including a plurality of wirings, and a wiring layer 35 provided on the wiring layer 34 and including a plurality of wirings.

The circuit chip C2 further includes a wiring layer 36 provided on the wiring layer 35 and including a plurality of wirings, a plurality of via plugs 37 provided on the wiring layer 36, and a plurality of metal pads 38 provided on the via plugs 37. The metal pad 38 is, for example, a copper (Cu) layer or an aluminum (Al) layer. The circuit chip C2 functions as a control circuit (logic circuit) that controls operation of the array chip C1. The control circuit is configured with the transistors 31 and the like, and is electrically connected to the metal pads 38.

The array chip C1 includes a plurality of metal pads 41 provided on the metal pad 38, and a plurality of via plugs 42 provided on the metal pads 41. The array chip C1 also includes a wiring layer 43 provided on the via plugs 42 and including a plurality of wirings, and a wiring layer 44 provided on the wiring layer 43 and including a plurality of wirings. The metal pad 41 is, for example, a Cu layer or an Al layer. The above-described via plug V is provided in the wiring layer 43.

The array chip C1 further includes a plurality of via plugs 45 provided on the wiring layer 44, a metal pad 46 provided on the via plugs 45 and on the insulating film 52, and a passivation film 47 provided on the metal pad 46 and on the insulating film 52. The metal pad 46 is, for example, a Cu layer or an Al layer, and functions as an external connection pad (bonding pad) of the semiconductor memory device of FIG. 9. The passivation film 47 is, for example, an insulating film such as a silicon oxide film, and is provided with an opening P through which an upper surface of the metal pad 46 is exposed. The metal pad 46 can be connected to a mounting board or other devices by bonding wires, solder balls, metal bumps, or the like via the opening P.

### Configuration of Contact Plug

Next, a configuration of the contact plug 62 will be described. Hereinafter, of staircase structures of first and second configuration examples, the staircase structure of the second configuration example will be described. It should be noted that the configuration of the contact plug 62 and the periphery thereof described below is also applicable to the staircase structure of the first configuration example.

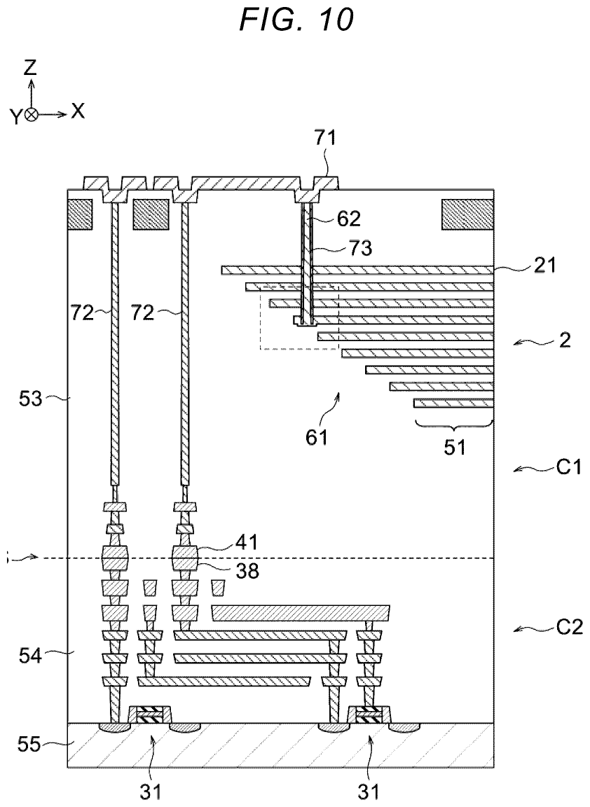

FIG. 10 is a cross-sectional view showing an example of the configuration of the semiconductor memory device according to the first embodiment.

The stacked body 2 includes conductive layers 21 and insulating layers 22 alternately stacked in a first direction (Z-axis direction). The stacked body 2 includes the memory cell array 51 and the staircase portion 61 having a staircase shape at end portions.

The contact plug 62 is electrically connected to the conductive layer 21 at the step surface of the staircase portion 61. The contact plug 62 extends from the step surface in the Z-axis direction to penetrate through the stacked body 2. Therefore, the contact plug 62 is led out from the stacked body 2 to an upper surface (rear surface) side of the array chip C1, that is, the widest conductive layer 21 side.

The wiring 71 is provided on the upper surface of the array chip C1. The wiring 71 is provided at a position opposite to the surface on which the step surface is provided relative to the stacked body 2 and extends in a direction approximately perpendicular to the Z-axis direction. The wiring 71 electrically connects the contact plug 62 to the contact plug 72.

The contact plug 72 electrically connects the wiring 71 to the transistor 31 provided on the circuit chip C2.

Therefore, a switch circuit (transistor 31) is electrically connected to the conductive layer 21 via the contact plugs 62 and 72, the wiring 71, and the like.

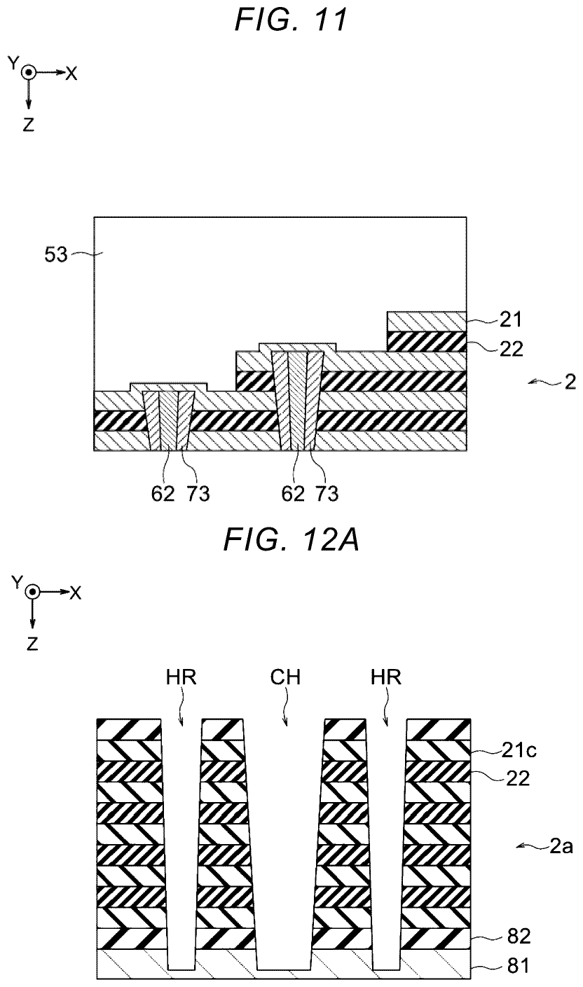

FIG. 11 is a cross-sectional view showing an example of the configuration of the semiconductor memory device according to the first embodiment. FIG. 11 shows an enlarged view of a dashed-line frame in FIG. 10.

An end portion of the contact plug 62 is connected to the conductive layer 21.

An insulating film 73 is provided around the contact plug 62. Thus, the contact plug 62 is electrically insulated from the conductive layer 21 penetrated by the contact plug 62.

Next, a manufacturing method of a semiconductor memory device will be described.

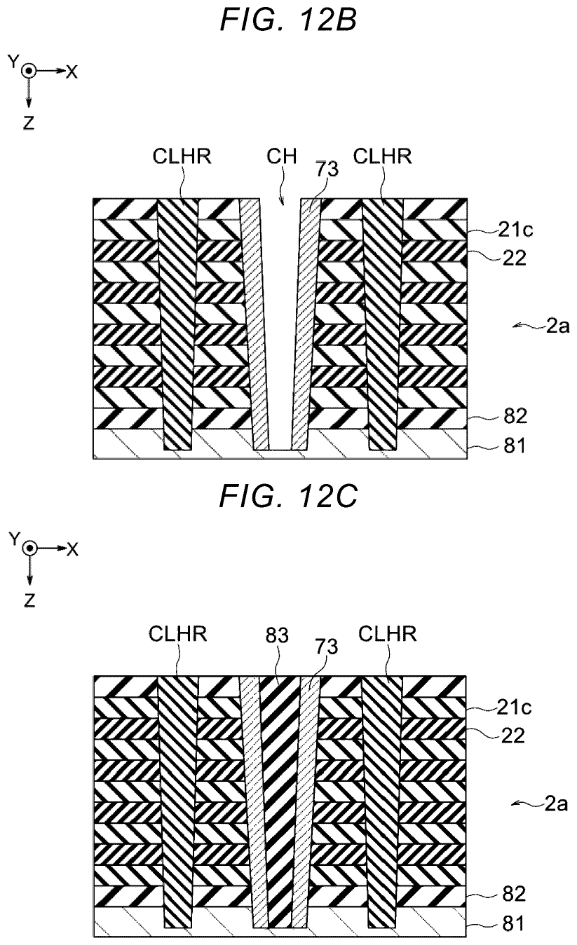

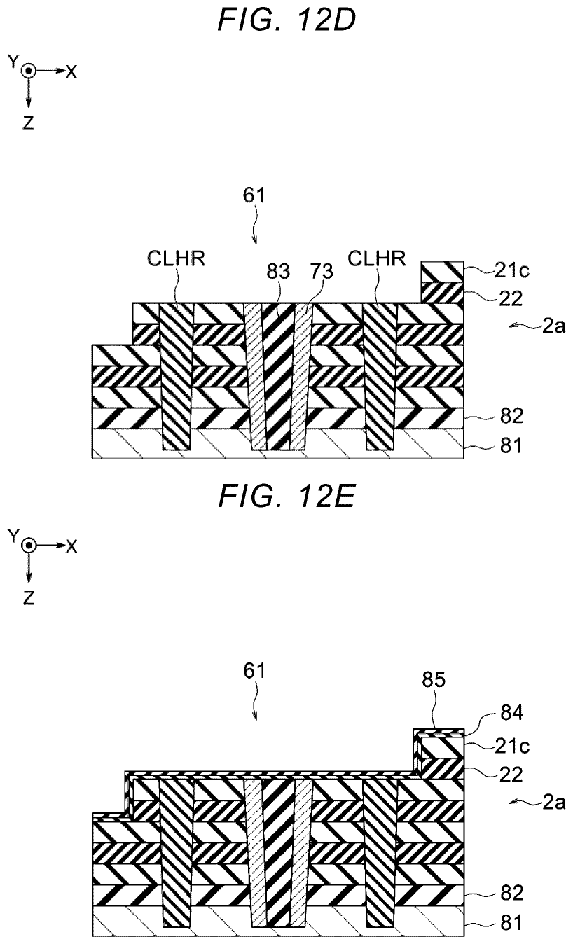

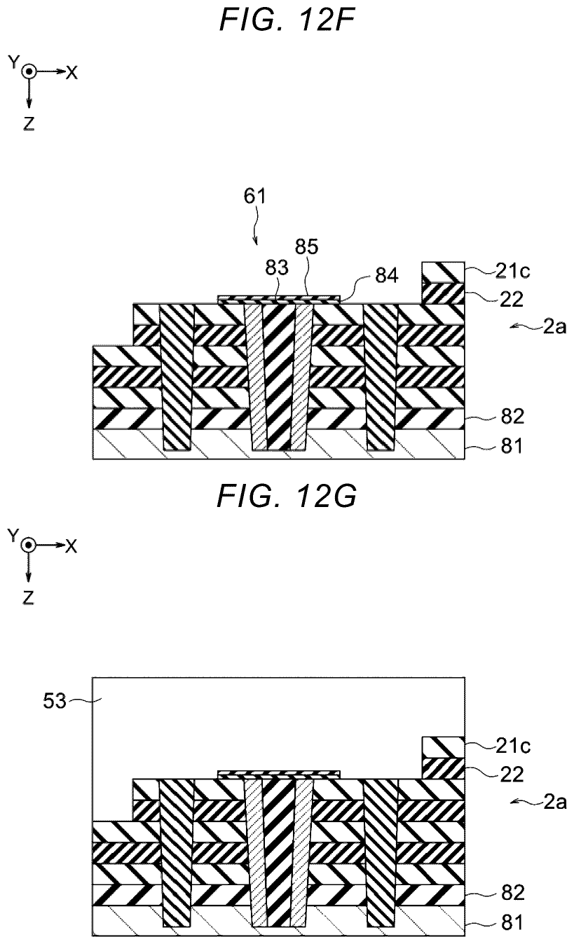

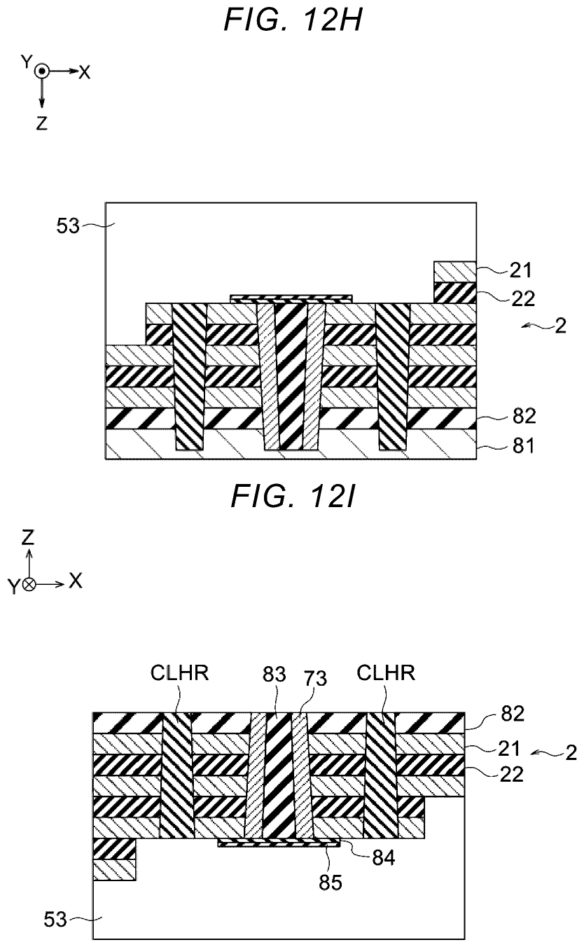

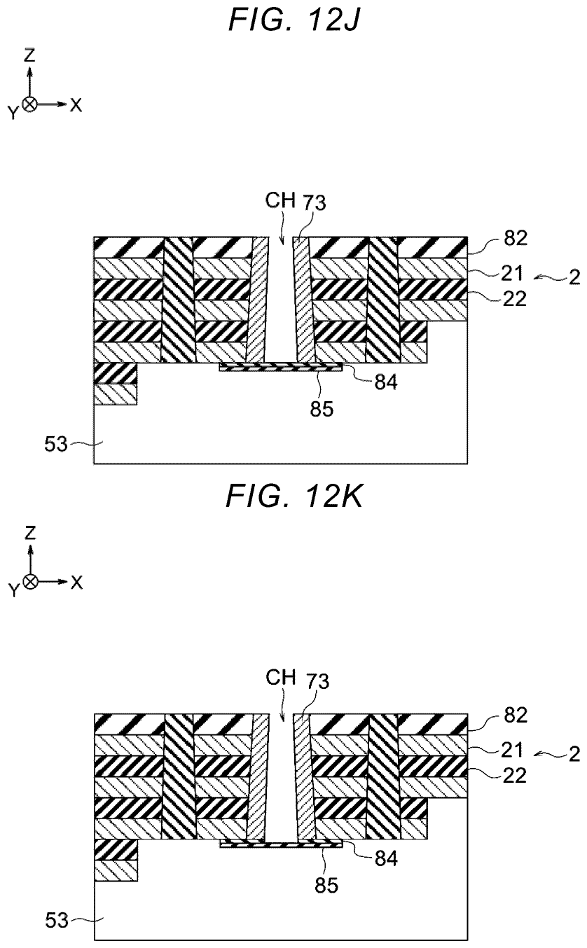

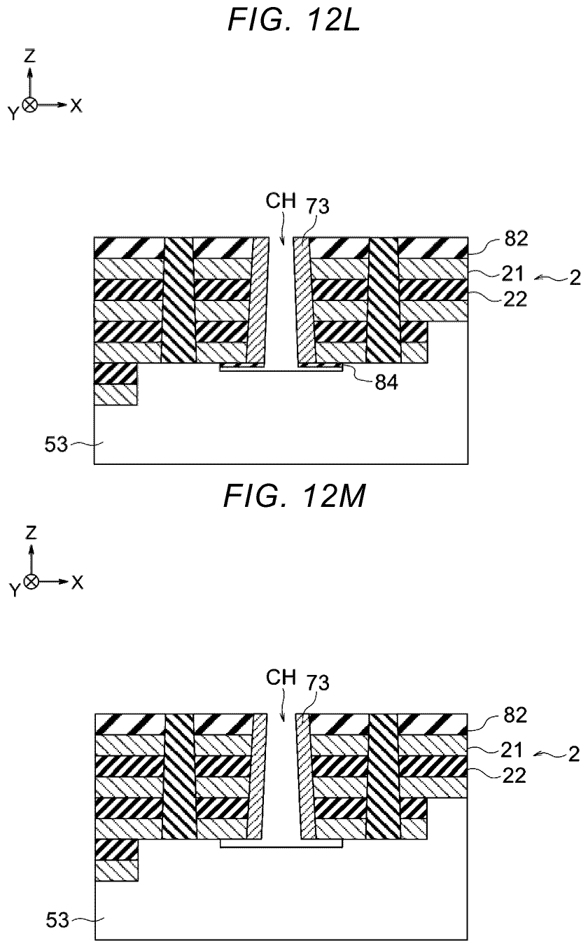

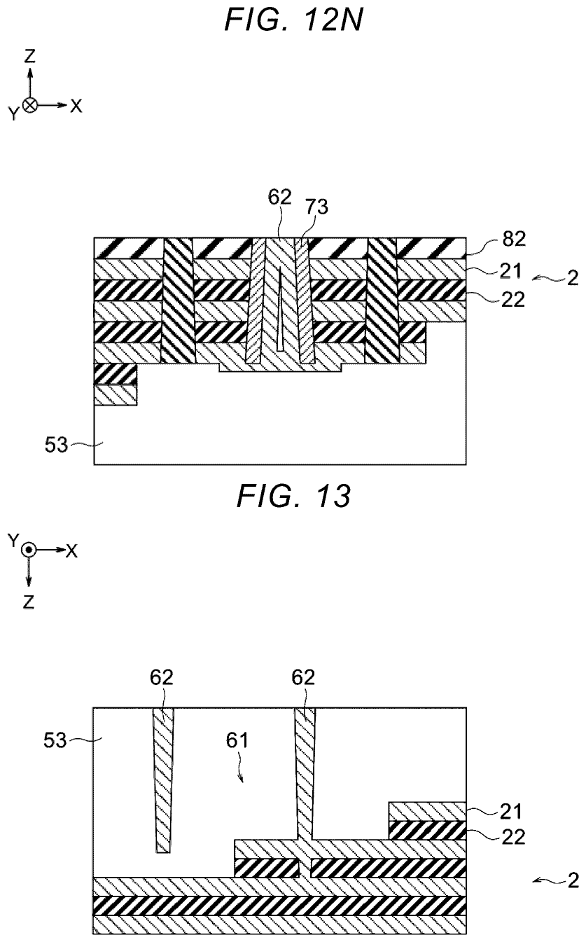

FIGS. 12A to 12N are cross-sectional views showing an example of a manufacturing method of the semiconductor memory device according to the first embodiment.

First, as shown in FIG. 12A, the holes HR and the contact holes CH penetrating a stacked body 2a in which sacrifice layers 21c and the insulating layers 22 are alternately stacked in a first direction (Z-axis direction) are formed.

Next, as shown in FIG. 12B, an insulating member is formed in the hole HR and the contact hole CH to form the insulating column CLHR in the hole HR, and the insulating film 73 (spacer) is formed on an inner surface of the contact hole CH.

Next, as shown in FIG. 12C, a sacrificial member 83 is buried in the contact hole CH.

Next, as shown in FIG. 12D, the staircase portion 61 is formed at the end portion of the stacked body 2a.

Next, as shown in FIG. 12E, an insulating film 84 is formed on the stacked body 2a, and an insulating film 85 is formed on the insulating film 84. The insulating film 84 functions as a stopper film of the contact plug 62. The insulating film 84 includes, for example, SiO₂. The insulating film 85 includes, for example, SiN.

Next, as shown in FIG. 12F, the insulating films 84 and 85 are processed such that the insulating films 84 and 85 remain on the sacrificial member 83.

Next, as shown in FIG. 12G, the interlayer insulating film 53 is formed on the stacked body 2a, and an upper surface of the interlayer insulating film 53 is planarized.

Next, as shown in FIG. 12H, the sacrifice layers 21c are replaced (substituted) with the conductive layers 21.

Next, as shown in FIG. 12I, a substrate 81 is peeled off. FIG. 12I is upside down compared to FIG. 12H. The substrate 81 is, for example, a silicon substrate.

Next, as shown in FIG. 12J, the sacrificial member 83 is removed.

Next, as shown in FIG. 12K, a part of the insulating film 84 is removed until the insulating film 85 is exposed.

Next, as shown in FIG. 12L, the insulating film 85 is removed.

Next, as shown in FIG. 12M, the insulating film 84 is removed. Thus, the conductive layer 21 is exposed in a space where the insulating film 84 is removed. A part of the insulating film 73 is also removed.

Next, as shown in FIG. 12N, a conductive member is embedded in the contact hole CH (a space in which the sacrificial member 83 and the insulating films 84 and 85 are removed). The conductive member is, for example, tungsten (W). Thus, the contact plug 62 connected to the conductive layer 21 exposed on the step surface is formed. In the example shown in FIG. 12N, voids are formed, but the voids may not necessarily be formed.

Thereafter, the wiring 71 and the like are formed, and the circuit chip C2 is bonded to complete the semiconductor memory device shown in FIG. 10.

As described above, according to the first embodiment, the contact plug 62 is electrically connected to the conductive layer 21 at the step surface of the staircase portion 61. The contact plug 62 extends from the step surface in the first direction (Z-axis direction) to penetrate through the stacked body 2.

As described above, configurations of the contact plug 62 and the periphery thereof according to the first embodiment can also be applied to the staircase structure according to the first configuration example shown in FIGS. 5 to 8B.

### First Comparative Example

FIG. 13 is a cross-sectional view showing an example of a configuration of a semiconductor memory device according to a first comparative example. The first comparative example differs from the first embodiment in that the contact plug 62 is formed after the staircase portion 61 is formed.

In the example shown in FIG. 13, of the two contact plugs 62, the left contact plug 62 is formed shallower than a desired depth and is not connected to the conductive layer 21 (open). Of the two contact plugs 62, the right contact plug 62 is formed deeper than a desired depth and penetrates the conductive layer 21 to be connected to the underlying conductive layer 21 (penetration). As the number of stacks increases and a film thickness of the conductive layer 21 decreases, open and penetration is more likely to occur. That is, it becomes difficult to appropriately connect the contact plug 62 to the conductive layer 21.

In contrast, in the first embodiment, the staircase portion 61 is formed after the contact hole CH (contact plug 62) is formed. Thus, assuming that the contact plug 62 penetrates the stacked body 2, the contact plug 62 extends from the rear surface side of the stacked body 2 and is connected to the conductive layer 21. As a result, opening and penetrating are prevented from occurring during formation of the contact plug 62. Therefore, the semiconductor memory device can be more appropriately formed.

### First Modification of First Embodiment

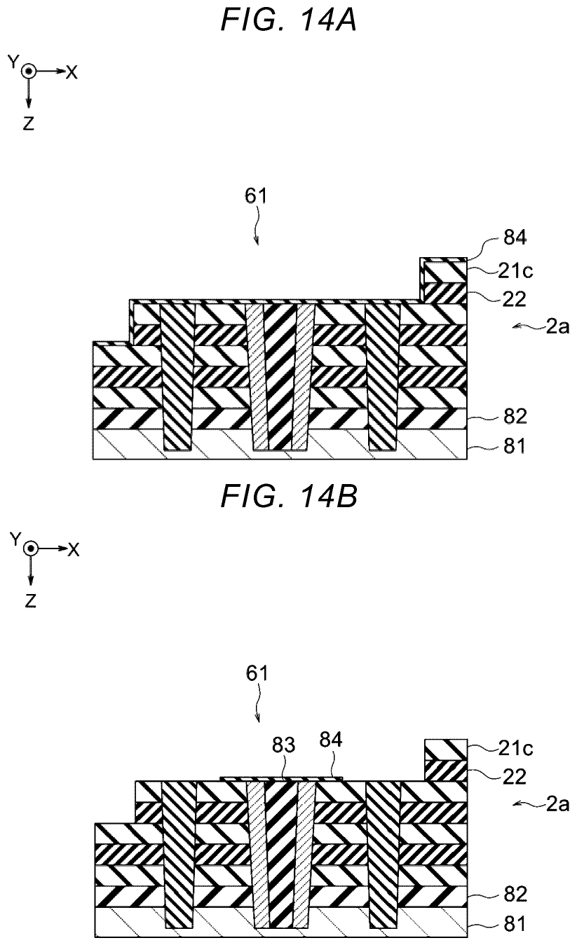

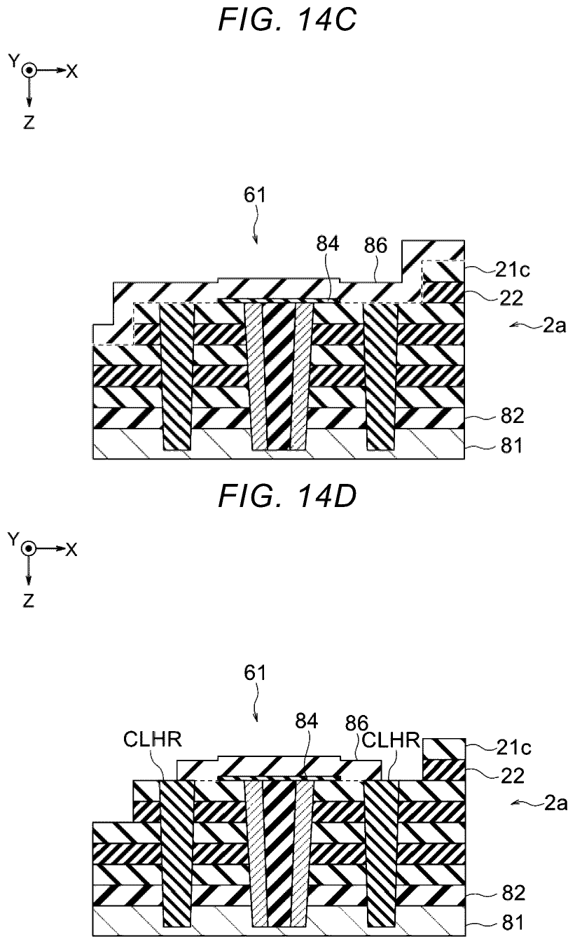

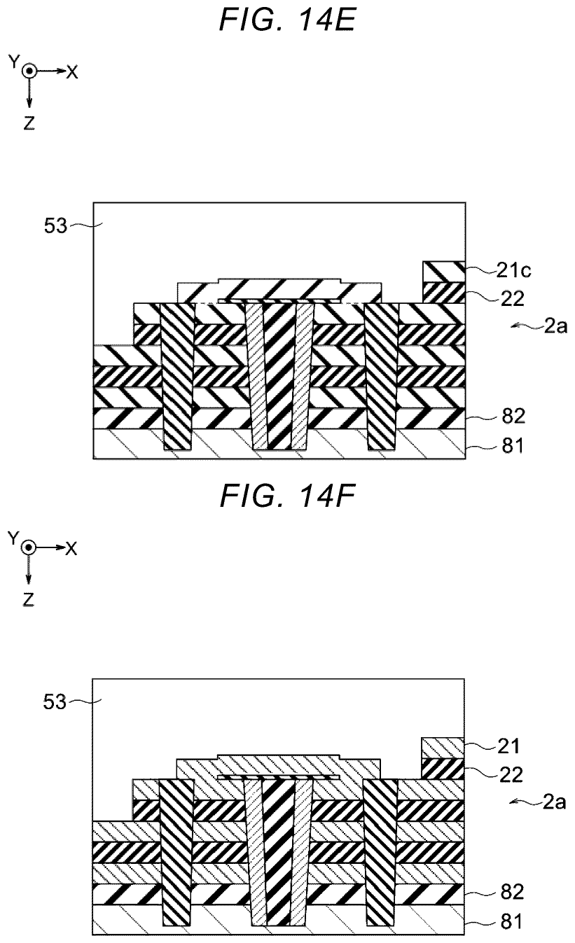

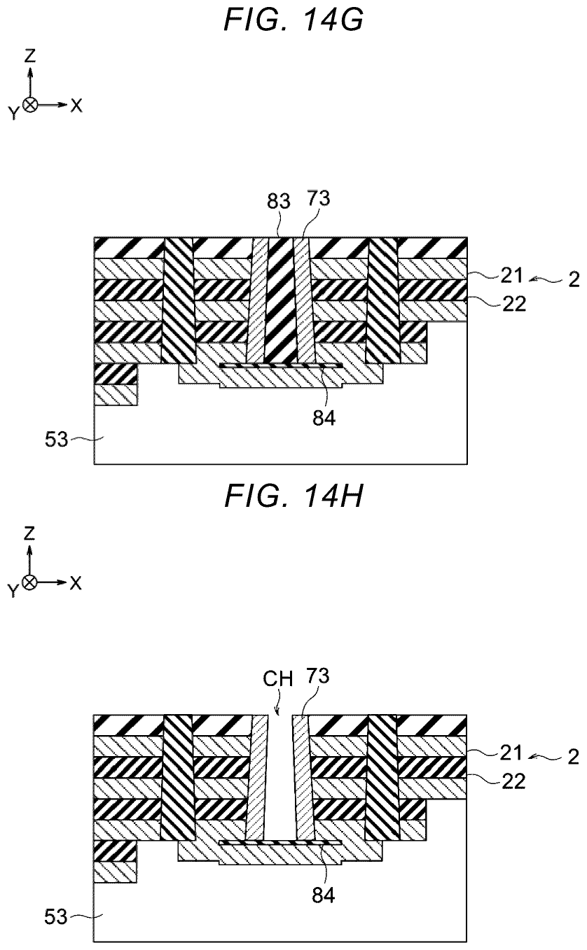

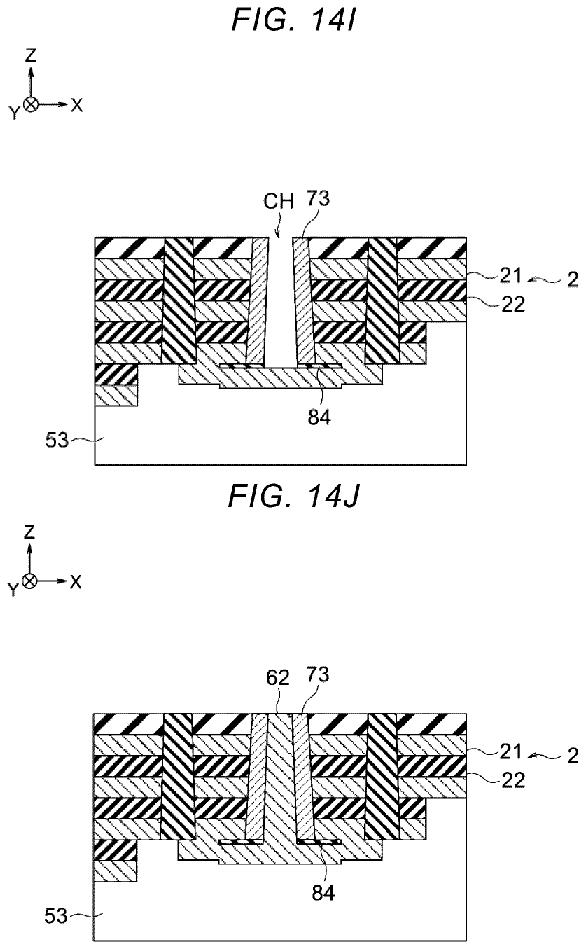

FIGS. 14A to 14J are cross-sectional views showing an example of a manufacturing method of a semiconductor memory device according to a first modification of the first embodiment. In the first modification of the first embodiment, the method of forming the contact plug 62 is different from that in the first embodiment. The step in FIG. 14A is performed after the same steps as those in FIGS. 12A to 12D.

After forming the staircase portion 61 (see FIG. 12D), the insulating film 84 is formed on the stacked body 2a as shown in FIG. 14A. In the first modification of the first embodiment, the insulating film 85 is not formed.

Next, as shown in FIG. 14B, the insulating film 84 is processed such that the insulating film 84 remains on the sacrificial member 83 exposed at the step surface.

Next, as shown in FIG. 14C, a sacrificial film 86 is formed on the stacked body 2a. The sacrificial film 86 includes, for example, SiN.

Next, as shown in FIG. 14D, the sacrificial film 86 is processed such that the sacrificial film 86 remains on the insulating film 84 and on the sacrifice layer 21c exposed on the step surface. In the example shown in FIG. 14D, a part of the sacrificial film 86 is also provided on the insulating columns CLHR.

Next, as shown in FIG. 14E, the interlayer insulating film 53 is formed, and the upper surface of the interlayer insulating film 53 is planarized.

Next, as shown in FIG. 14F, the sacrifice layer 21c and the sacrificial film 86 are replaced with the conductive layer 21.

Next, as shown in FIG. 14G, the substrate 81 is peeled off. It should be noted that FIG. 14G is upside down compared to FIG. 14F.

Next, as shown in FIG. 14H, the sacrificial member 83 is removed.

Next, as shown in FIG. 14I, a part of the insulating film 84 is removed until the conductive layer 21 is exposed.

Next, as shown in FIG. 14J, a conductive member is buried in the contact hole CH. The conductive member is, for example, tungsten (W). Thus, the contact plug 62 connected to the conductive layer 21 is formed.

Thereafter, the wiring 71 and the like are formed, and the circuit chip C2 is bonded to complete the semiconductor memory device shown in FIG. 10.

As in the first modification of the first embodiment, the method of forming the contact plug 62 may be different. Also here, the same effects as in the first embodiment can be achieved.

### Second Embodiment

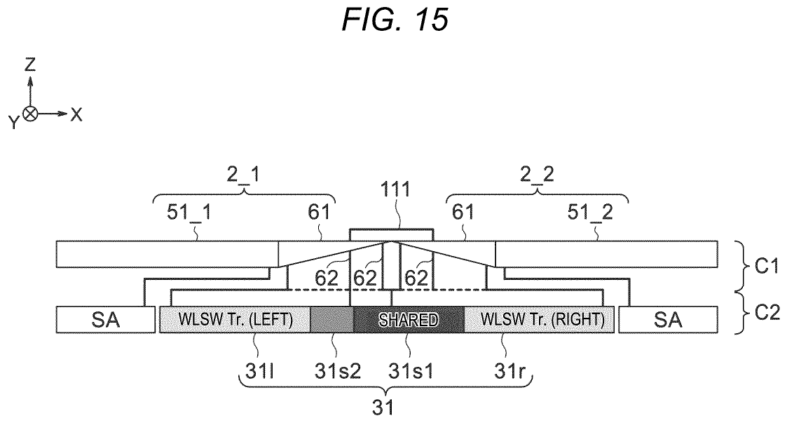

FIG. 15 is a diagram showing an example of a configuration of a semiconductor memory device according to a second embodiment.

The array chip C1 is provided with two stacked bodies 2_1 and 2_2 and a wiring 111. The stacked body 2_1 includes a memory cell array 51_1 and the staircase portion 61. The stacked body 2_2 includes a memory cell array 51_2 and the staircase portion 61.

The two stacked bodies 2_1 and 2_2 are disposed such that the staircase portions 61 face each other. Therefore, the two stacked bodies 2_1 and 2_2 are separated in the center.

The contact plugs 62 connected to the two stacked bodies 2_1 and 2_2, respectively, extend to penetrate the stacked bodies 2_1 and 2_2 on a side where the step surface is provided and on a side opposite to the side where the step surface is provided.

The contact plug 62 is electrically connected to the switch circuit (transistor 31) provided on the circuit chip C2.

The circuit chip C2 is provided with a sense amplifier SA and a switch circuit. The switch circuit includes a plurality of transistors 31.

Two sense amplifiers SA are provided such that the switch circuit is interposed therebetween. The two sense amplifiers SA are connected to the two stacked bodies 2_1 and 2_2, respectively.

The plurality of transistors 31 include transistors 311, 31r, 31s1, and 31s2.

The transistor 311 is connected to the stacked body 2_1 via the contact plug 62.

The transistor 31r is connected to the stacked body 2_2 via the contact plug 62.

The transistor 31s1 is disposed between the transistor 311 and the transistor 31r. The transistor 31s1 is shared by the two stacked bodies 2_1 and 2_2. The transistor 31s1 can be shared by electrically connecting the conductive layers 21 in the stacked bodies 2_1 and 2_2 to each other via a wiring in a wiring layer provided on the circuit chip C2 side of the array chip C1. However, due to wiring restrictions in the wiring layers or the like, it is difficult to connect all layers of the conductive layer 21. For example, the conductive layers 21 in the same layer are electrically connected to each other.

The transistor 31s2 is disposed between the transistor 311 and the transistor 31r. The transistor 31s2 is shared by the two stacked bodies 2_1 and 2_2. The transistor 31s2 can be shared by electrically connecting the conductive layers 21 in the stacked bodies 2_1 and 2_2 to each other via the wiring 111. For example, the conductive layers 21 in the same layer are electrically connected to each other. It should be noted that in the example shown in FIG. 15, the transistor 31s2 is disposed below the staircase portion 61 of the stacked body 2_1, thus disposed between the transistor 311 and the transistor 31s1.

That is, the contact plug 62 connected to the stacked body 2_1 is electrically connected to the switch circuit (transistor 31). The contact plug 62 connected to the stacked body 2_1 is electrically connected to the contact plug 62 connected to the stacked body 2_2. The end portion on the step surface side of the contact plug 62 connected to the stacked body 2_1 is not connected to any wiring or the like.

The wiring 111 is provided at a position on the rear surface side of the stacked bodies 2_1 and 2_2, that is, on a side opposite to the side on which the step surface is provided relative to the stacked bodies 2_1 and 2_2. As will be described later, the wiring 111 electrically connects the contact plug 62 penetrating the stacked body 2_1 to the contact plug 62 penetrating the stacked body 2_2.

FIG. 16 is a cross-sectional view showing an example of the configuration of the semiconductor memory device according to the second embodiment.

The wiring 111 is provided in the insulating film 52 provided above the semiconductor layer (buried source line BSL). The wiring 111 is electrically connected to the contact plug 62 via a contact plug C111. The contact plug C111 penetrates the buried source line BSL and is connected to the upper end of the contact plug 62.

The contact plugs 62 of the two stacked bodies 2_1 and 2_2 are electrically connected to each other by the wiring 111. Thus, the transistor 31s2 of the switch circuit is shared by the two stacked bodies 2_1 and 2_2.

An insulating film 112 is provided on the insulating film 52 and the wiring 111.

An insulating film 113 is provided on the insulating film 112.

A wiring 114 is provided on the insulating film 112. The wiring 114 is electrically connected to a buried source line BSL via a contact plug C114. The contact plug C114 penetrates the insulating film 52 and is connected to the buried source line BSL in the cell area.

Insulating layers 115, 116, and 117 are provided on a side of the array chip C1 facing the circuit chip C2. The word wiring layer 63 is provided in the insulating layer 117.

The two contact plugs 62 that share the transistor 31s1 are electrically connected to each other by a wiring provided in the word wiring layer 63.

Of the two contact plugs 62 that share the transistor 31s2, a wiring is led out from the contact plug 62 on the stacked body 2_1 side and connected to the transistor 31s2. Of the two contact plugs 62 that share the transistor 31s2, no wiring or the like is led out from the contact plug 62 on the stacked body 2_2 side.

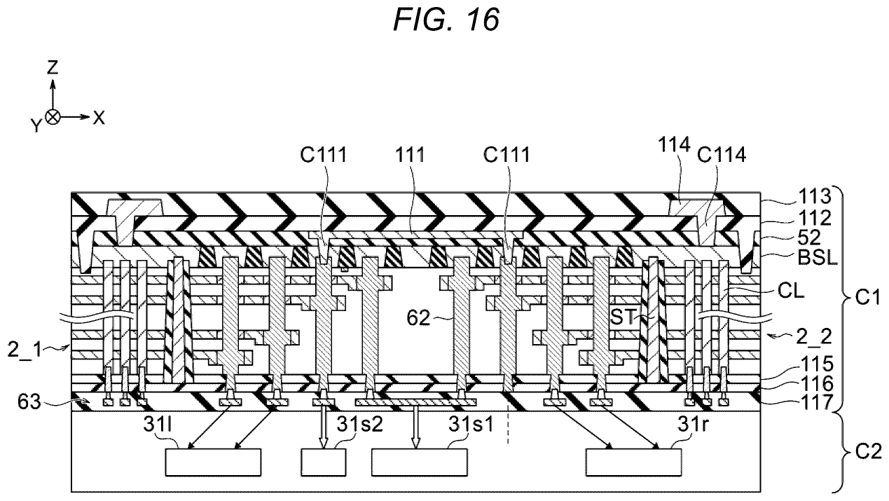

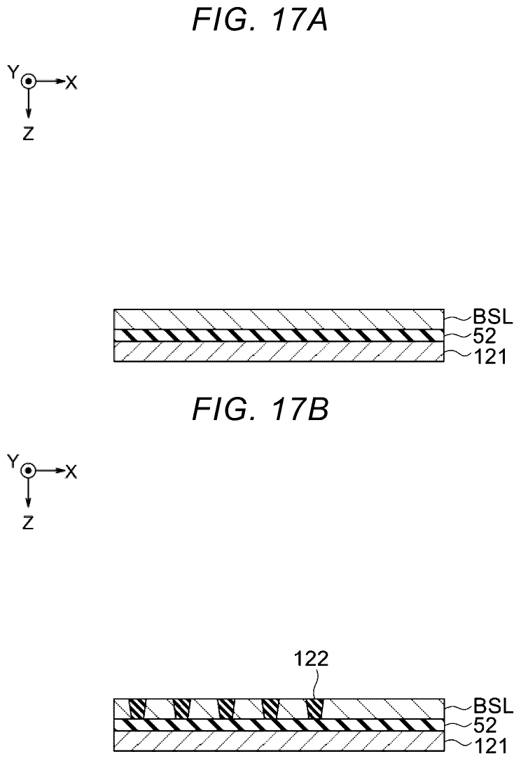

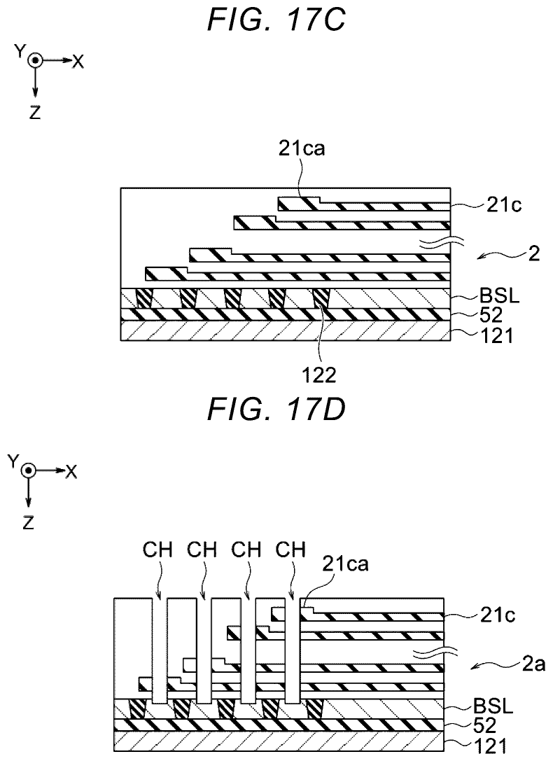

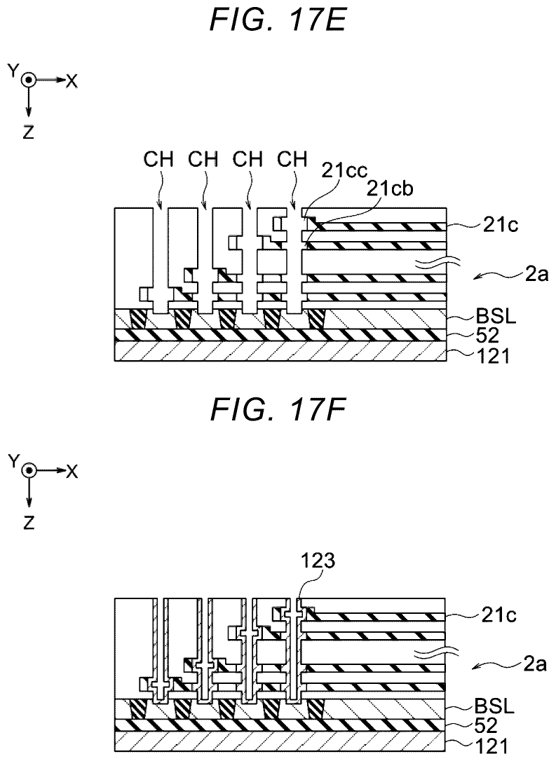

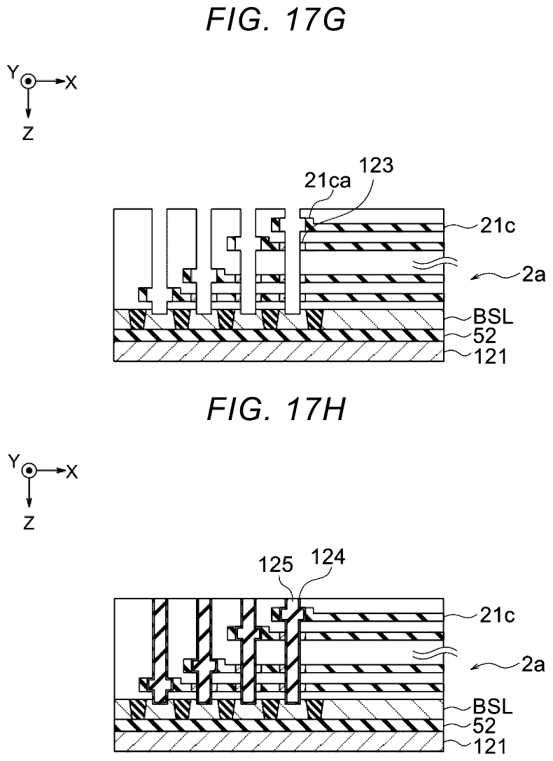

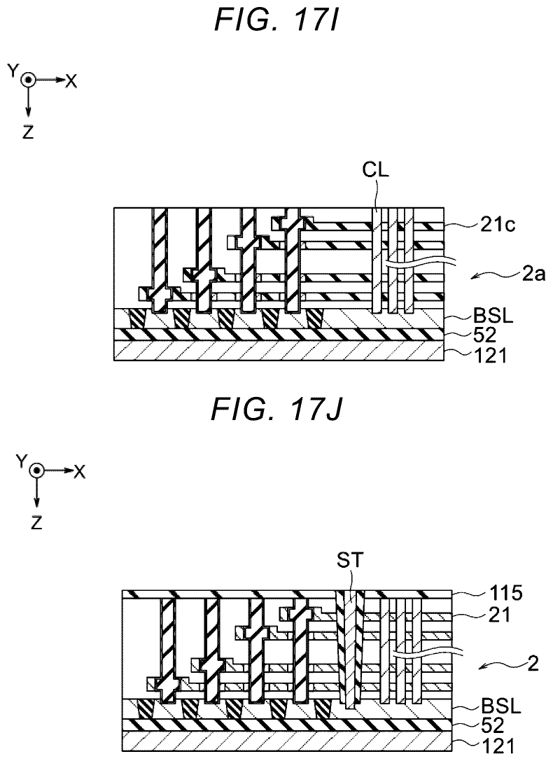

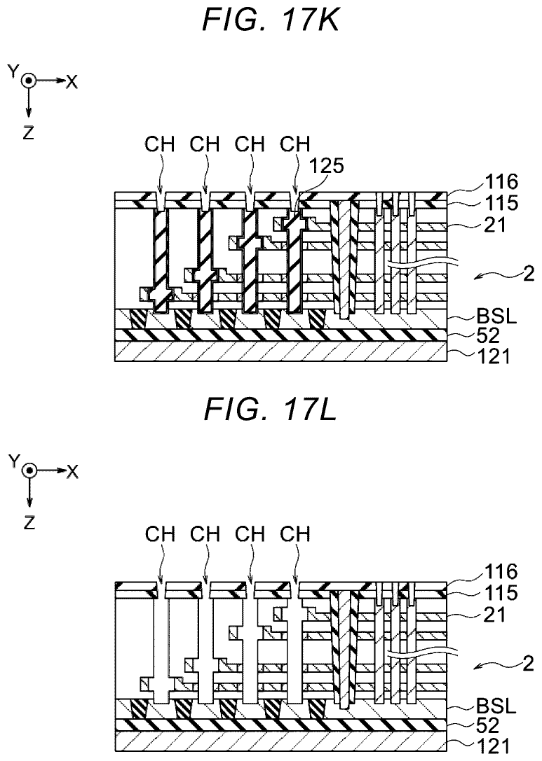

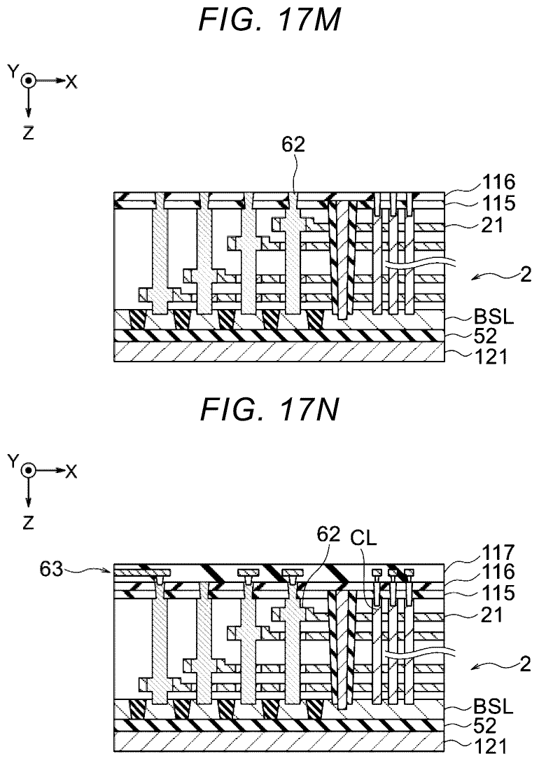

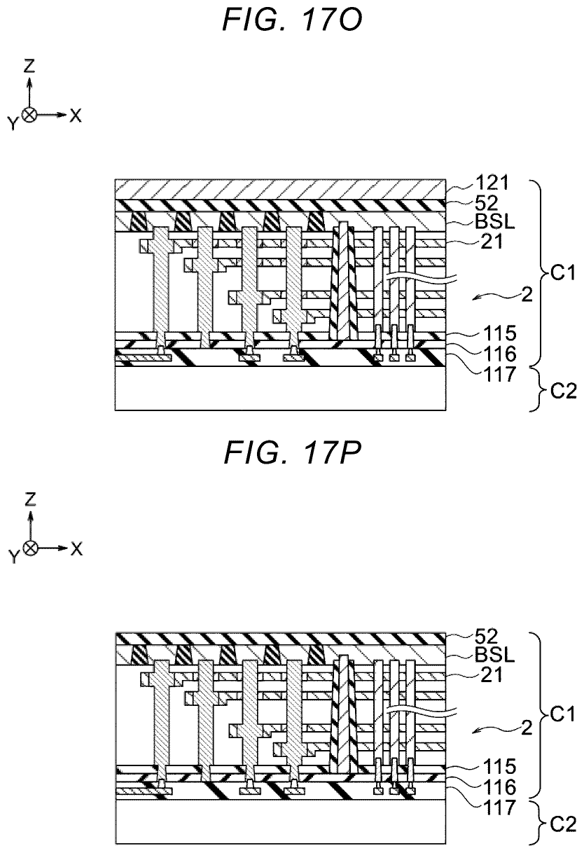

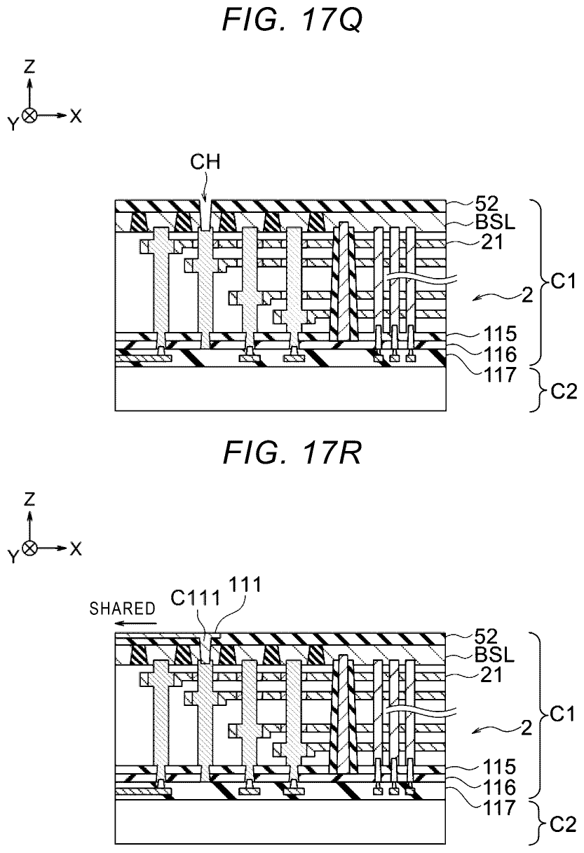

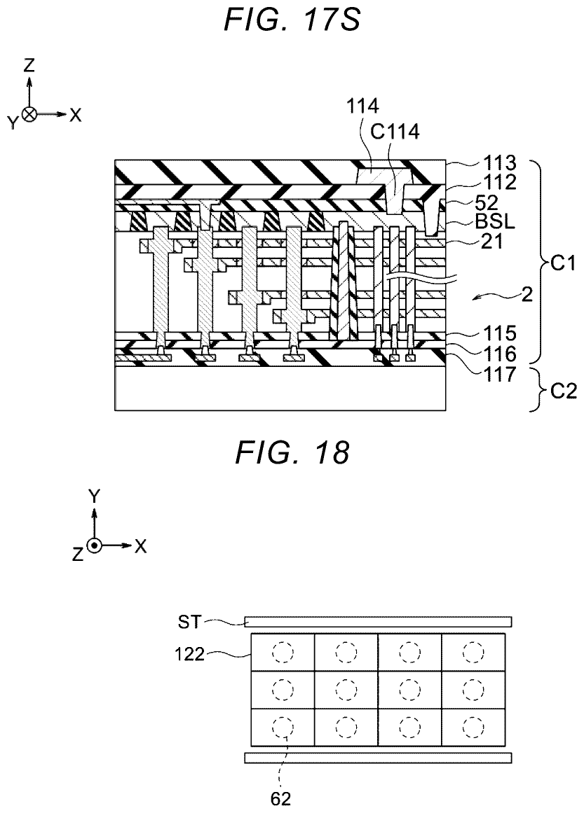

FIGS. 17A to 17S are cross-sectional views showing an example of a manufacturing method of the semiconductor memory device according to the second embodiment. In the following, one of the two stacked bodies 2_1 and 2_2 formed at the same time will be described.

First, as shown in FIG. 17A, the insulating film 52 is formed on a substrate 12I, and a semiconductor layer (buried source line BSL) is formed on the insulating film 52. The substrate 121 is, for example, a silicon substrate.

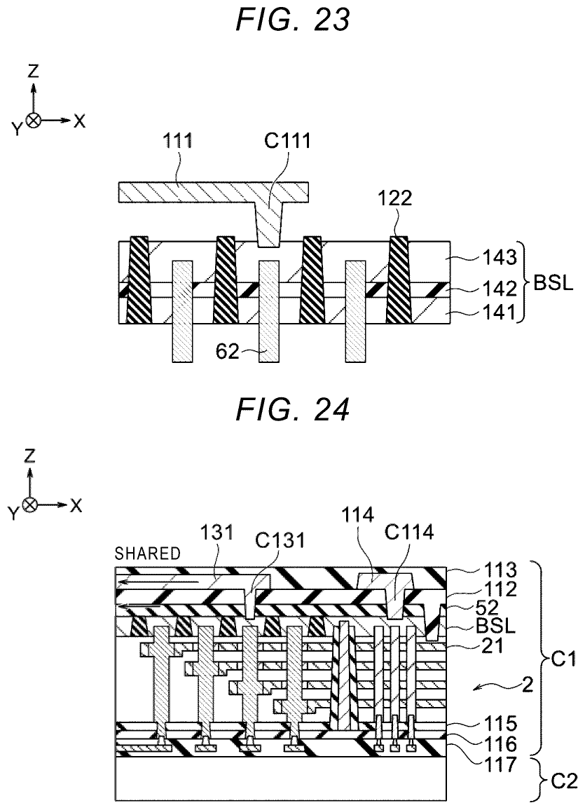

The buried source line BSL is, for example, a polysilicon layer. More specifically, the buried source line BSL has a structure in which a semiconductor layer (for example, a polysilicon layer), an insulating layer, and a semiconductor layer (for example, a polysilicon layer) are stacked (see FIG. 23).

Next, as shown in FIG. 17B, the buried source line BSL is processed to form insulating members 122 that insulate the buried source line BSL at positions where the contact plugs 62 are formed.

FIG. 18 is a plan view showing an example of an embedding pattern of the insulating member 122 according to the second embodiment.

As shown in FIG. 18, dashed-line circles indicate locations where the contact plugs 62 are to be formed. A pattern of the insulating member 122 is formed to separate the contact plugs 62 from each other. Thus, the contact plugs 62 are electrically insulated from each other.

Next, as shown in FIG. 17C, the stacked body 2a is formed, and the staircase portions 61 facing each other are formed.

The sacrifice layer 21c is provided with a thick film portion 21ca at a position corresponding to the step surface, that is, an end portion connected to the penetrating contact plug 62. The thick film portion 21ca has a thickness in the Z-axis direction greater than other portions of the sacrifice layer 21c.

Next, as shown in FIG. 17D, contact holes CH are formed to pass through the step surfaces and penetrate the stacked body 2a in the Z-axis direction. The contact hole CH is a through via hole that exposes the semiconductor layer BSL. The contact hole CH is formed to penetrate through the thick film portion 21ca.

Next, as shown in FIG. 17E, a portion of the sacrifice layer 21c is removed (recessed) from an inner periphery surface of the contact hole CH. Thus, a plurality of recess portions 21cb are formed at positions of the sacrifice layers 21c not connected to the contact plug 62. A recess portion 21cc is formed at a position of the sacrifice layer 21c connected to the contact plug 62.

Next, as shown in FIG. 17F, an insulating layer 123 is formed on the inner periphery surface of the contact hole CH. Here, a film thickness of the insulating layer 123 is larger than half the width of the recess portion 21cb in the Z-axis direction (thickness of the sacrifice layer in the Z-axis direction). Therefore, the recess portion 21cb is embedded with the insulating layer 123. Meanwhile, the film thickness of the insulating layer 123 is smaller than half the width of the recess portion 21cc in the Z-axis direction (thickness of the thick film portion of the sacrifice layer in the Z-axis direction). Therefore, the recess portion 21cc is not embedded with the sacrifice layer.

Next, as shown in FIG. 17G, a portion of the insulating layer 123 is removed (recessed). In the present step, portions of the insulating layer 123 formed on the side surface of the insulating layer 123, in the thick film portion 21ca of the sacrifice layer 21c, and on an upper surface of the semiconductor layer BSL are removed. Thus, the thick film portion 21ca of the sacrifice layer 21c and the semiconductor layer BSL are exposed.

Next, as shown in FIG. 17H, an insulating layer 124 (liner film) is formed on the inner surface of the contact hole CH, and the contact hole CH is embedded with a sacrificial member 125. The insulating layer 124 includes, for example, SiO₂.

Next, as shown in FIG. 17I, the memory hole MH is formed, and the columnar portion CL is formed in the memory hole MH.

Next, as shown in FIG. 17J, the insulating layer 115 is formed, the slit ST is formed, and the sacrifice layer 21c is replaced with the conductive layer 21.

Next, as shown in FIG. 17K, the contact hole CH is formed on the sacrificial member 125. Thus, an upper surface of the sacrificial member 125 is exposed.

Next, as shown in FIG. 17L, the sacrificial member 125 and the insulating layer 124 (liner film) are removed.

Next, as shown in FIG. 17M, the contact plug 62 is formed in the contact hole CH. The contact plug 62 is electrically connected to the conductive layer 21 at the step surface.

Next, as shown in FIG. 17N, the word wiring layer 63 including the contact plugs 62 and the wiring led out from the columnar portion CL is formed, and the insulating layer 117 is formed.

Next, as shown in FIG. 17O, the array chip C1 is bonded to the circuit chip C2. It should be noted that FIG. 17O is upside down compared to FIG. 17N.

Next, as shown in FIG. 17P, the substrate 121 is peeled off.

Next, as shown in FIG. 17O, the contact hole CH is formed from the upper surface (rear surface) side of the array chip C1, that is, from the widest conductive layer 21 side. The contact hole CH is formed to penetrate the insulating film 52 and the semiconductor layer BSL and expose the contact plug 62.

Next, as shown in FIG. 17R, the wiring 111 and the contact plug C111 are formed. The wiring 111 and the contact plug C111 are formed, for example, by processing the insulating film 52 and burying a conductive material therein. The wiring 111 and the contact plug C111 electrically connect the contact plug 62 connected to the stacked body 2_1 to the contact plug 62 connected to the stacked body 2_2.

Next, as shown in FIG. 17S, the insulating film 112, the wiring 114, the contact plug C114, and the insulating film 113 are formed.

As described above, according to the second embodiment, the contact plug 62 extends to penetrate the stacked body 2_1 on the side where the step surface is provided, and is electrically connected to the switch circuit. The contact plug 62 extends to penetrate the stacked body 2_1 on the side opposite to the side where the step surface is provided, and is electrically connected to the contact plug 62 of the stacked body 2_2. Thus, the transistor 31s2 of the switch circuit is shared by the two stacked bodies 2_1 and 2_2, thereby reducing the chip area.

### Second Comparative Example

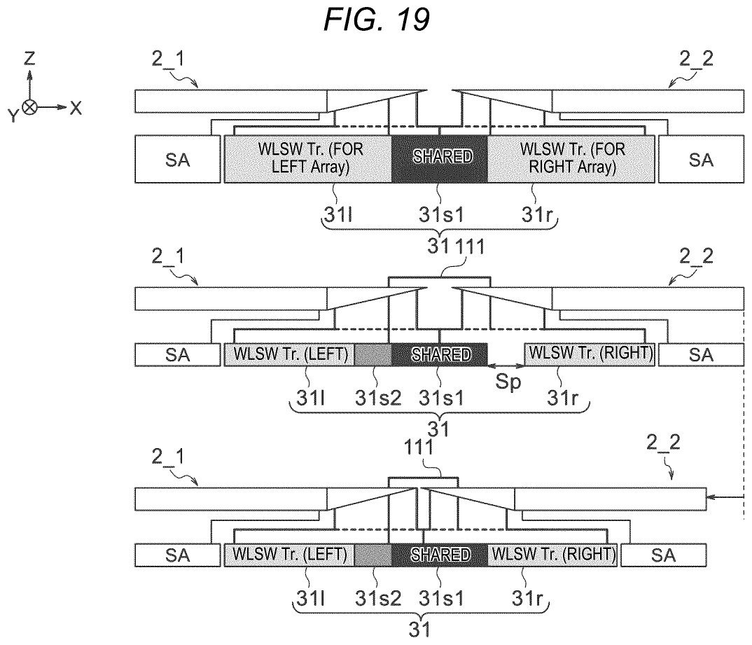

FIG. 19 is a diagram showing an example of configurations of semiconductor memory devices according to the second embodiment and a second comparative example. An upper part of FIG. 19 shows the semiconductor memory device according to the second comparative example. A middle part shows a space Sp that can be reduced by providing the wiring 111 according to the second embodiment. A lower part shows the semiconductor memory device according to the second embodiment.

The second comparative example is different from the second embodiment in that the wiring 111 is not provided and sharing of the switch circuit by using the wiring 111 is not realized.

As shown in the upper part, in the second comparative example, the transistors 311 and 31r of the switch circuits corresponding to the two stacked bodies 2_1 and 2_2, respectively, are provided.

In the middle part, the wiring 111 is provided, and the transistor 31s2 below the stacked body 2_1 is shared by the two stacked bodies 2_1 and 2_2 such that the space Sp that can be reduced is formed below the stacked body 2_2.

As shown in the lower part, in the second embodiment, the chip area corresponding to the space Sp is reduced.

As such, in the second embodiment, the switch circuit (transistor 31s2) is shared, thereby reducing the chip area.

### First Modification of Second Embodiment

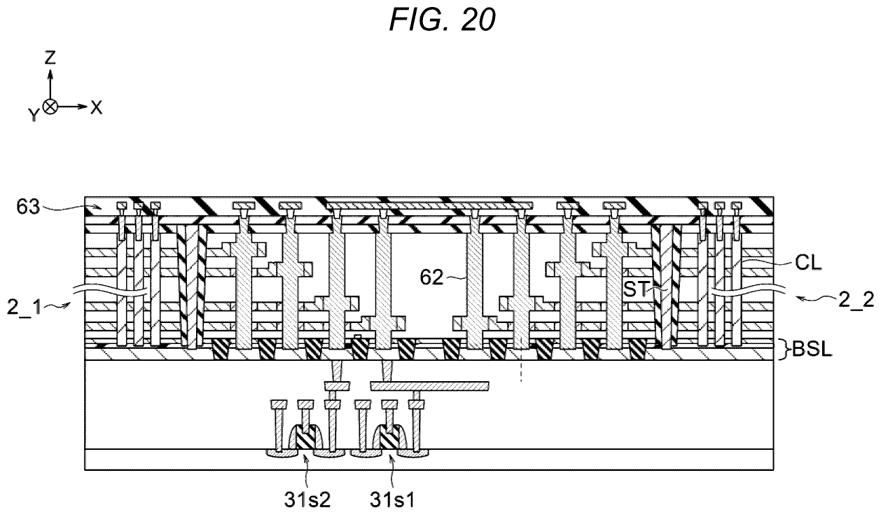

FIG. 20 is a diagram showing an example of a configuration of a semiconductor memory device according to a first modification of the second embodiment. The first modification of the second embodiment differs from the second embodiment in that the configuration of the chip to which the semiconductor memory device is bonded is not provided, and the switch circuit is provided below the stacked bodies 2_1 and 2_2.

In the example shown in FIG. 20, the switch circuit (transistor 31) is provided below the stacked bodies 2_1 and 2_2, similarly to the configuration shown in FIG. 1.

Similar to FIG. 16 according to the second embodiment, the transistor 31s2 of the switch circuit is shared by the two stacked bodies 2_1 and 2_2. Similar to FIG. 16 according to the second embodiment, of the two contact plugs 62 that share the transistor 31s2, no wiring is led out from the contact plug 62 on the side of the stacked body 2_2.

As in the first modification of the second embodiment, the semiconductor memory device may be provided with the switch circuit below the stacked bodies 2_1 and 2_2. Also here, the same effects as in the second embodiment can be achieved.

### Second Modification of Second Embodiment

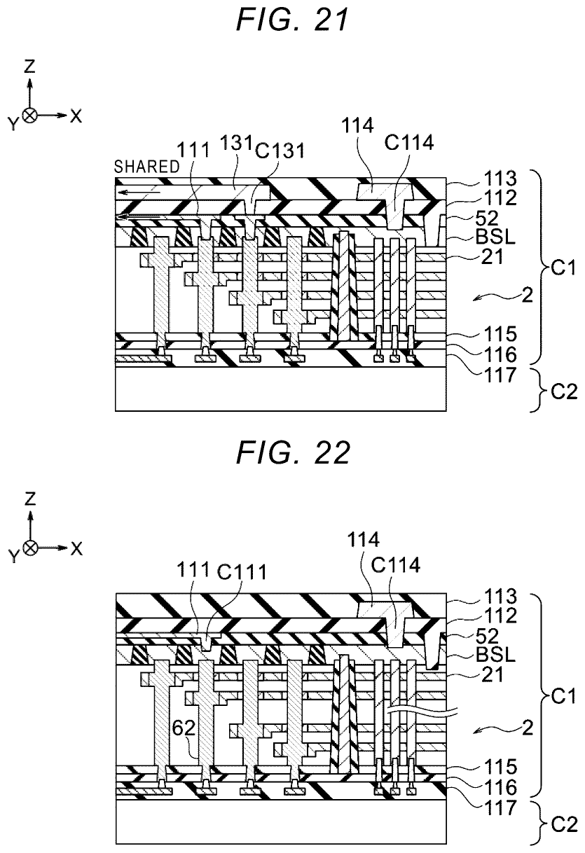

FIG. 21 is a cross-sectional view showing an example of a configuration of a semiconductor memory device according to a second modification of the second embodiment. The second modification of the second embodiment differs from the second embodiment in that a wiring 131 for sharing is provided in a layer different from the layer of the wiring 111.

The wiring 131 is provided in the same wiring layer as the wiring 114. Accordingly, it is possible to increase the number of wiring for sharing the switch circuits. Also, it is possible to further increase the number of shared switch circuits (transistors), and further reduce the chip area.

In the example shown in FIG. 21, a contact plug C131 penetrates the insulating film 112 and is connected to a wiring provided in the same layer as the wiring 111.

As in the second modification of the second embodiment, the wiring 131 for sharing may be provided in a layer different from the layer of the wiring 111. Also here, the same effects as in the second embodiment can be achieved.

### Third Modification of Second Embodiment

FIG. 22 is a cross-sectional view showing an example of a configuration of a semiconductor memory device according to a third modification of the second embodiment. The third modification of the second embodiment differs from the second embodiment in that the contact plug C111 of the wiring 111 is not in direct contact with the contact plug 62.

The contact plug C111 extends to a position that reaches inside of the buried source line BSL. The contact plug C111 is not in direct contact with the contact plug 62, but is electrically connected to the contact plug 62 via the buried source line BSL. The buried source line BSL includes a doped semiconductor layer.

FIG. 23 is a cross-sectional view showing an example of the configuration of the semiconductor memory device according to the third modification of the second embodiment. FIG. 23 is an enlarged view of the buried source line BSL and the periphery thereof in FIG. 22.

The buried source line BSL includes a semiconductor layer 141, an insulating layer 142, and a semiconductor layer 143 that are stacked. The semiconductor layers 141 and 143 are, for example, polysilicon layers. The insulating layer 142 is, for example, a silicon oxide film.

The contact plug 62 extends to penetrate through the insulating layer 142 and reach the semiconductor layer 143 (FIG. 23), or when the insulating layer 142 is removed, the contact plug C111 and the contact plug 62 can be electrically connected to each other via the buried source line BSL.

As in the third modification of the second embodiment, the contact plug C111 of the wiring 111 may not be in direct contact with the contact plug 62. Also here, the same effects as in the second embodiment can be achieved.

### Fourth Modification of Second Embodiment

FIG. 24 is a cross-sectional view showing an example of a configuration of a semiconductor memory device according to a fourth modification of the second embodiment. The fourth modification of the second embodiment differs from the second modification of the second embodiment in that the contact plug C131 of the wiring 131 is not in direct contact with the contact plug 62. That is, the fourth modification of the second embodiment is a combination of the second modification of the second embodiment and the third modification of the second embodiment.

The contact plug C131 extends to penetrate through the insulating film 52 and the insulating film 112 to a position reaching the inside of the buried source line BSL. The contact plug C131 is not in direct contact with the contact plug 62, but is electrically connected to the contact plug 62 via the buried source line BSL. The buried source line BSL includes a doped semiconductor layer. Thus, the contact plug C131 of the wiring 131 can be formed simultaneously with the contact plug C114 of the wiring 114 in the same step. Thus, it is possible to reduce an increase in the number of steps.

As in the fourth modification of the second embodiment, the contact C131 of the wiring 131 may not be in direct contact with the contact plug 62. Also here, the same effects as in the second modification of the second embodiment can be achieved.

### Fifth Modification of Second Embodiment

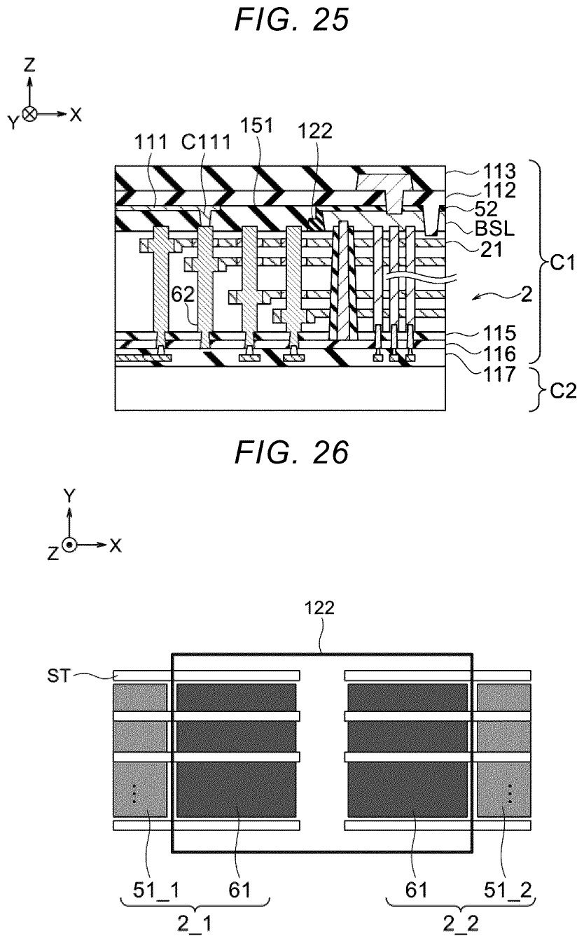

FIG. 25 is a cross-sectional view showing an example of a configuration of a semiconductor memory device according to a fifth modification of the second embodiment. The fifth modification of the second embodiment is different from the second embodiment in that the buried source line BSL is not provided at a position corresponding to the staircase portion 61. In the fifth modification of the second embodiment, an arrangement of the insulating member 122 is different from that in the second embodiment.

The insulating member 122 is disposed between the staircase portion 61 and the memory cell array 51.

The buried source line BSL is removed on the left side of the insulating member 122 shown in FIG. 25, and an insulating film 151 is provided.

FIG. 26 is a plan view showing an example of a configuration of the insulating member 122 according to the fifth modification of the second embodiment.

The insulating member 122 is provided, for example, in a ring shape surrounding the staircase portion 61 of each of the stacked bodies 2_1 and 2_2. The insulating member 122 is provided in, for example, a rectangular ring shape. In the ring of the insulating member 122, the buried source line BSL is removed and the insulating film 151 is provided.

Thus, it is possible to reduce an influence of a breakdown voltage between the wiring 111 (contact plug C111) and the buried source line BSL when the insulating film 52 shown in FIG. 25 is thin in the Z-axis direction.

As in the fifth modification of the second embodiment, the buried source line BSL may not be provided at a position corresponding to the staircase portion 61. Also here, the same effects as in the second embodiment can be achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a plurality of conductive layers and insulating layers alternately stacked in a first direction; and
a contact plug electrically connected to a corresponding one of the conductive layers and extending from a step surface of the corresponding conductive layer in the first direction to penetrate through a corresponding portion of the stacked body.

2. The semiconductor memory device according to claim 1, further comprising:
a first chip including the stacked body and the contact plug; and
a second chip stacked with respect to the first chip and including a switch circuit, wherein
the switch circuit is electrically connected to the conductive layer via the contact plug.

3. The semiconductor memory device according to claim 1, further comprising:
a first wiring provided to extend in a direction perpendicular to the first direction at a position opposite to a side on which the step surface is provided relative to the stacked body, the first wiring being electrically connected to the contact plug.

4. A manufacturing method of a semiconductor memory device, the method comprising:
forming a hole penetrating through a stacked body in a first direction, the stacked body including sacrifice layers and insulating layers alternately stacked on top of one another;
forming a first insulating film along an inner surface of the hole;
filling the hole with a sacrificial member;
forming a staircase portion over the hole filled with the sacrificial member;
forming a second insulating film on the sacrificial member, the second insulating film formed on a step surface of the staircase portion;
replacing the sacrifice layer with a conductive layer;
removing the sacrificial member to again expose the hole;
removing, through the hole, a portion of the second insulating film; and
forming a contact plug in the re-exposed hole, the contact plug being electrically connected to the conductive layer.

5. The manufacturing method of a semiconductor memory device according to claim 4, the method further comprising:
after forming the second insulating film, forming a third insulating film on the second insulating film, wherein
removing a portion of the second insulating film includes removing a portion of the second insulating film until the third insulating film is exposed, and
the manufacturing method further includes, after removing a portion of the second insulating film, removing the third insulating film, and removing the second insulating film.

6. The manufacturing method of a semiconductor memory device according to claim 4, further comprising:
after forming the second insulating film, forming a first sacrificial film on the second insulating film and on the sacrifice layer exposed on the step surface, wherein
replacing the sacrifice layer with the conductive layer includes replacing the sacrifice layer and the first sacrificial film with the conductive layer, and
removing a portion of the second insulating film includes removing a portion of the second insulating film until the conductive layer is exposed.

7. A semiconductor memory device comprising:
a first stacked body including a plurality of first conductive layers and a plurality of first insulating layers alternately stacked in a first direction, the first stacked body further including a first staircase portion; and
a second stacked body including a plurality of second conductive layers and a plurality of second insulating layers alternately stacked in the first direction, the second stacked body further including a second staircase portion, the first staircase portion and the second staircase portion facing each other;
a first contact plug electrically connected to a corresponding one of the first conductive layers and extending from a first step surface of the corresponding first conductive layer in the first direction to penetrate through a corresponding portion of the first stacked body; and
a second contact plug electrically connected to corresponding one of the second conductive layers and extending from a second step surface of the corresponding second conductive layer in the first direction to penetrate through a corresponding portion of the second stacked body, wherein
the first contact plug extends to penetrate the first stacked body on a side on which the first step surface is provided and is electrically connected to a switch circuit, and
the first contact plug extends to penetrate the first stacked body on a side opposite to the side on which the first step surface is provided and is electrically connected to the second contact plug.

8. The semiconductor memory device according to claim 7, wherein
the switch circuit is shared by the first conductive layer electrically connected to the first contact plug, and the second conductive layer is electrically connected to the second contact plug.

9. The semiconductor memory device according to claim 7, wherein
the second contact plug extends to penetrate through the second stacked body on a side on which the second step surface is provided, and
an end portion of the second contact plug is not connected to a wiring.

10. The semiconductor memory device according to claim 7, wherein
the second contact plug extends to penetrate through the second stacked body on a side opposite to a side on which the second step surface is provided, and
the semiconductor memory device further includes a second wiring extending in a direction approximately perpendicular to the first direction at a position on a side opposite to a side on which the first step surface and the second step surface are provided relative to the first stacked body and the second stacked body, the second wiring electrically connecting the first contact plug to the second contact plug.

11. A manufacturing method of a semiconductor memory device, the method comprising:
forming a first stacked body and a second stacked body each including sacrifice layers and insulating layers alternately stacked in a first direction;
forming a first staircase portion at an end portion of the first stacked body and a second staircase portion at an end portion of the second stacked body, the first staircase portion and the second staircase portion facing each other;
forming a first hole passing through a first step surface of the first staircase portion and penetrating the first stacked body in the first direction and a second hole passing through a second step surface of the second staircase portion and penetrating the second stacked body in the first direction;
replacing the sacrifice layer with a conductive layer;
forming a first contact plug electrically connected to the conductive layer at the first step surface and a second contact plug electrically connected to the conductive layer at the second step surface in the first hole and the second hole, respectively; and
forming a second wiring electrically connecting the first contact plug to the second contact plug at a position on a side opposite to a side on which the first step surface and the second step surface are provided relative to the first stacked body and the second stacked body.

12. The manufacturing method of a semiconductor memory device according to claim 11, the method further comprising:
before forming the first stacked body and the second stacked body, forming a fourth insulating film on the substrate, forming a semiconductor layer on the fourth insulating film, and forming an insulating member insulating the semiconductor layer at positions where the plurality of first contact plugs and the plurality of second contact plugs are formed.
